(19) United States
(12) Patent Application Publication
(10) Pub. No.: US 2023/0091726 A1
(43) Pub. Date: Mar. 23, 2023

(54) DISPLAY DEVICE

(71) Applicant: Samsung Display Co., LTD., Yongin-si (KR)

(72) Inventors: Do Yeong PARK, Yongin-si (KR); In Woo KIM, Yongin-si (KR); Chong Chul CHAI, Yongin-si (KR); Chang Woo KWON, Yongin-si (KR); Kyung Bae KIM, Yongin-si (KR); Dae Cheol KIM, Yongin-si (KR); Jong Hwan PARK, Yongin-si (KR); Yong Tae CHO, Yongin-si (KR); Kook Hyun CHOI, Yongin-si (KR)

(73) Assignee: Samsung Display Co., LTD., Yongin-si (KR)

(21) Appl. No.: 17/945,373

(22) Filed: Sep. 15, 2022

(30) Foreign Application Priority Data
Sep. 17, 2021 (KR) 10-2021-0125071

(51) Int. Cl. H01L 33/62; H01L 27/15; H01L 33/38

(52) U.S. Cl. CPC H01L 33/62; H01L 27/156; H01L 33/382

(57) ABSTRACT

A display device includes a substrate including a display area and a non-display area; pixels disposed in the display area and including respective light emitting units; a first conductive pattern disposed between the pixels; and a power source line disposed in the non-display area and electrically connected to the first conductive pattern. Each of the light emitting units includes a light emitting element, a first pixel electrode disposed on a first end of the light emitting element, and a second pixel electrode disposed on a second end of the light emitting element. The first conductive pattern and the second pixel electrode are disposed on a same layer.

### CROSS-REFERENCE TO RELATED APPLICATION(S

The application claims priority to and the benefit of Korean Patent Application No. 10-2021-0125071 under 35 U.S.C. § 119, filed Sep. 17, 2021, in the Korean Intellectual Property Office (KIPO), the entire contents of which are hereby incorporated by reference.

### BACKGROUND

### 1. Technical Field

The disclosure relates to a display device.

### 2. Description of the Related Art

In recent years, interest in information displays has increased. Accordingly, research and development on display devices have been continuously conducted.

### SUMMARY

A technical problem to be solved by the disclosure is to provide a display device capable of protecting pixels from electrostatic discharge.

Technical problems of the disclosure are not limited to the above-described technical problem, and other technical problems that are not mentioned will be clearly understood by those skilled in the art from the following description.

A display device according to an embodiment of the disclosure may include a substrate including a display area and a non-display area; pixels disposed in the display area and including light emitting units; a first conductive pattern disposed between the pixels; and a power source line disposed in the non-display area and electrically connected to the first conductive pattern. Each of the light emitting units may include a light emitting element, a first pixel electrode disposed on a first end of the light emitting element, and a second pixel electrode disposed on a second end of the light emitting element. The first conductive pattern and the second pixel electrode may be disposed on a same layer.

In an embodiment, the first conductive pattern may include first pattern portions extending in a first direction in the display area, and second pattern portions extending in a second direction in the display area.

In an embodiment, the first conductive pattern may further include a third pattern portion disposed in the non-display area and connected to the first pattern portions and the second pattern portions.

In an embodiment, the third pattern portion may surround the display area when viewed on a plane.

In an embodiment, the first conductive pattern may extend to the non-display area and may overlap the power source line and the first conductive pattern may be directly connected to the power source line.

In an embodiment, the display device may further include a first pad electrically connected to the power source line. The first conductive pattern may not be directly connected to the power source line, and the first conductive pattern may be electrically connected to the first pad.

In an embodiment, the first conductive pattern and second pixel electrodes of the light emitting units may be separated from each other.

In an embodiment, the power source line may be electrically connected to the second pixel electrodes of the light emitting units.

In an embodiment, the first conductive pattern and the second pixel electrodes of the light emitting units may be integral with each other.

In an embodiment, the first pixel electrodes of the light emitting units and the first conductive pattern may be disposed on different layers, and the first pixel electrode of the light emitting units and the second pixel electrodes of the light emitting units may be disposed on different layers.

In an embodiment, the display device may further include a second conductive pattern overlapping the first conductive pattern and electrically connected to the first conductive pattern.

In an embodiment, the second conductive pattern and the first pixel electrodes of the light emitting units may be disposed on a same layer.

In an embodiment, the first conductive pattern may have a mesh shape and may include first pattern portions extending in a first direction in the display area; and second pattern portions extending in a second direction in the display area. The second conductive pattern may have a mesh shape and may include third pattern portions overlapping the first pattern portions; and fourth pattern portions overlapping the second pattern portions.

In an embodiment, the second conductive pattern and the first pixel electrodes of the light emitting units may be separated from each other.

In an embodiment, the pixels may further include pixel circuits electrically connected to the light emitting units.

In an embodiment, the display device may further include a circuit layer disposed on a surface of the substrate and including the power source line and the pixel circuits of the pixels; and a display layer disposed on the circuit layer and including the first conductive pattern and the light emitting units of the pixels.

In an embodiment, the display device may further include a color filter layer and an encapsulation layer that are disposed above the display layer.

In an embodiment, the color filter layer and the encapsulation layer may be disposed above the surface of the substrate where the circuit layer and the display layer are disposed.

A display device according to an embodiment of the disclosure may include pixels including light emitting units, each of the light emitting units including a light emitting element and pixel electrodes electrically connected to the light emitting element; and a conductive pattern having a mesh shape and disposed around the pixels to surround the light emitting units. The conductive pattern and at least one of the pixel electrodes may be disposed on a same layer.

In an embodiment, the display device may further include a power source line electrically connected to the conductive pattern.

Details of other embodiments are included in the detailed description and drawings.

### BRIEF DESCRIPTION OF THE DRAWINGS

The accompanying drawings, which are incorporated in and constitute a part of this specification, illustrate the embodiments together with the description thereof.

FIG. 1 is a perspective view illustrating a light emitting element according to an embodiment of the disclosure.

FIG. 2 is a schematic cross-sectional view illustrating the light emitting element according to an embodiment of the disclosure.

FIG. 3 is a plan view illustrating a display device according to an embodiment of the disclosure.

FIGS. 4 and 5 are circuit diagrams illustrating sub-pixels according to embodiments of the disclosure.

FIG. 6 is a plan view illustrating a display area according to an embodiment of the disclosure.

FIG. 7 is a schematic cross-sectional view illustrating the display area according to an embodiment of the disclosure.

FIGS. 8 to 11 are plan views illustrating display devices according to embodiments of the disclosure.

FIGS. 12 to 14 are plan views illustrating display layers of the display area according to embodiments of the disclosure.

FIG. 15 is a schematic cross-sectional view illustrating a display area according to an embodiment of the disclosure.

FIG. 16 is a plan view illustrating a display layer of the display area according to an embodiment of the disclosure.

FIG. 17 is a schematic cross-sectional view illustrating the display area according to an embodiment of the disclosure.

### DETAILED DESCRIPTION OF THE ILLUSTRATED EMBODIMENTS

The disclosure may be modified in various ways and may have various forms, and specific embodiments will be illustrated in the drawings and described in detail herein. In the following description, the singular forms also include the plural forms unless the context clearly includes only the singular.

Meanwhile, it should be understood that the disclosure is not limited to the embodiments disclosed below, and includes all modifications, equivalents and substitutes included in the spirit and scope of the disclosure. In addition, each of the embodiments disclosed below may be implemented alone or in combination with at least one other embodiment.

Throughout the drawings, the same or similar elements will be given by the same reference numerals and symbols as much as possible even though they are shown in different drawings. In describing embodiments of the disclosure with reference to the drawings, repeated descriptions of the same or similar elements will be omitted or simplified.

In describing embodiments of the disclosure, the term “connection (or coupling)” may refer generically to a physical and/or electrical connection (or coupling). Also, it may refer generically to direct or indirect connection (or coupling), and may refer generically to integral or non-integral connection (or coupling).

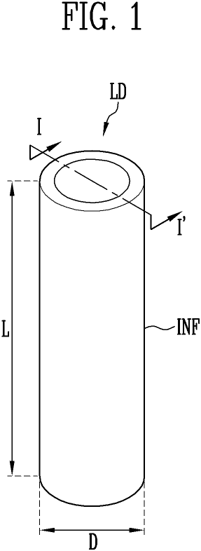

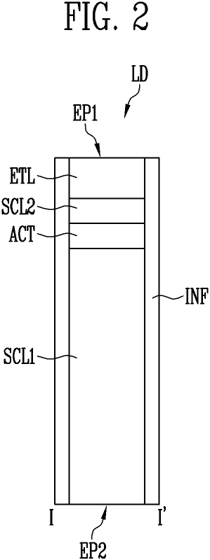

FIG. 1 is a perspective view illustrating a light emitting element LD according to an embodiment of the disclosure. FIG. 2 is a schematic cross-sectional view illustrating the light emitting element LD according to an embodiment of the disclosure. For example, FIG. 1 shows an example of the light emitting element LD that can be used as a light source of a display device according to an embodiment of the disclosure. FIG. 2 shows, a cross section of the light emitting element LD taken along line I - I' of FIG. 1.

Referring to FIGS. 1 and 2, the light emitting element LD may include a first semiconductor layer SCL1, an active layer ACT (also referred to as a light emitting layer), and a second semiconductor layer SCL2 sequentially arranged and/or stacked in one direction (for example, a longitudinal direction). The light emitting element LD may further include an insulating film INF surrounding the outer peripheral surface (for example, a side surface) of the first semiconductor layer SCL1, the active layer ACT, and the second semiconductor layer SCL2. According to an embodiment, the light emitting element LD may further include an electrode layer ETL disposed on the second semiconductor layer SCL2. The insulating film INF may or may not cover at least a portion of the outer peripheral surface of the electrode layer ETL. According to an embodiment, the light emitting element LD may further include another electrode layer disposed on one surface (for example, a lower surface) of the first semiconductor layer SCL1.

In an embodiment, the light emitting element LD may be provided in a rod shape. In describing embodiments of the disclosure, the rod shape may include a rod-like shape or a bar-like shape of various types, such as a cylindrical shape or a polygonal column shape, and the shape of the cross-section is not particularly limited. In an embodiment, a length L of the light emitting element LD may be greater than a diameter D (or a width of the cross-section) of the light emitting element LD.

The light emitting element LD may have a first end EP1 and a second end EP2 facing each other. For example, the light emitting element LD may have the first end EP1 and the second end EP2 at both ends in the longitudinal direction (or thickness direction). The first end EP1 of the light emitting element LD may include a first bottom surface (or an upper surface) of the light emitting element LD and/or a peripheral area thereof. The second end EP2 of the light emitting element LD may include a second bottom surface (or a lower surface) of the light emitting element LD and/or a peripheral area thereof.

The first semiconductor layer SCL1, the active layer ACT, the second semiconductor layer SCL2, and the electrode layer ETL may be sequentially disposed in a direction from the second end EP2 to the first end EP1 of the light emitting element LD. For example, the electrode layer ETL (or the second semiconductor layer SCL2) may be disposed at the first end EP1 of the light emitting element LD, and the first semiconductor layer SCL1 (or another electrode layer adjacent to the first semiconductor layer SCL1 and electrically connected to the first semiconductor layer SCL1) may be disposed at the second end EP2 of the light emitting element LD.

The first semiconductor layer SCL1 may include a first conductivity type semiconductor layer including a first conductivity type dopant. For example, the first semiconductor layer SCL1 may be an N-type semiconductor layer including an N-type dopant.

According to an embodiment, the first semiconductor layer SCL1 may include a nitride-based semiconductor material or a phosphide-based semiconductor material. For example, the first semiconductor layer SCL1 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AlP, and InP. In an embodiment, the first semiconductor layer SCL1 may include an N-type dopant such as Si, Ge, Sn, or the like. However, the material constituting the first semiconductor layer SCL1 is not limited thereto, and various other materials may be used to form the first semiconductor layer SCL1.

The active layer ACT may be disposed on the first semiconductor layer SCL1. The active layer ACT may include a single-quantum well or multi-quantum well structure. When a voltage equal to or greater than a threshold voltage is applied to both ends of the light emitting element LD, the light emitting element LD may emit light while electron-hole pairs are combined in the active layer ACT.

According to an embodiment, the active layer ACT may emit light in a wavelength band of visible light, for example, light in a wavelength in a range of approximately 400 nm to approximately 900 nm. For example, the active layer ACT may emit blue light having a wavelength in a range of approximately 450 nm to approximately 480 nm, green light having a wavelength in a range of approximately 480 nm to approximately 560 nm, or red light having a wavelength in a range of approximately 620 nm to 750 nm. The color and/or wavelength band of the light generated in the active layer ACT may be changed.

According to an embodiment, the active layer ACT may include a nitride-based semiconductor material or a phosphide-based semiconductor material. For example, the active layer ACT may include a nitride-based semiconductor material including at least one of GaN, AlGaN, InGaN, InGaAlN, AlN, InN, and AlInN, or a phosphide-based semiconductor material including at least one of GaP, GaInP, AlGaP, AlGaInP, AlP and InP. Various other materials may be used to form the active layer ACT.

According to an embodiment, the active layer ACT may include an element related to the color (or wavelength band) of light. The color of the light generated in the active layer ACT may be controlled by adjusting the content and/or composition ratio of the element. For example, the active layer ACT may be formed of a multi-layer structure in which GaN layers and InGaN layers are alternately and/or repeatedly stacked with each other, and may emit light of the color corresponding to the content and/or composition ratio of indium (In) included in the InGaN layer. Accordingly, the light emitting element LD of a desired color may be manufactured by adjusting the content and/or composition ratio of indium (In) included in the active layer ACT.

The second semiconductor layer SCL2 may be disposed on the active layer ACT. The second semiconductor layer SCL2 may include a second conductivity type semiconductor layer including a second conductivity type dopant. For example, the second semiconductor layer SCL2 may be a P-type semiconductor layer including a P-type dopant.

According to an embodiment, the second semiconductor layer SCL2 may include a nitride-based semiconductor material or a phosphide-based semiconductor material. For example, the second semiconductor layer SCL2 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AlP and InP. In an embodiment, the second semiconductor layer SCL2 may include a P-type dopant such as Mg. Various other materials may be used to form the second semiconductor layer SCL2.

In an embodiment, the first semiconductor layer SCL1 and the second semiconductor layer SCL2 may include a same semiconductor material, but may include dopants of different conductivity types. In another embodiment, the first semiconductor layer SCL1 and the second semiconductor layer SCL2 may include a different semiconductor material and may include dopants of different conductivity types.

According to an embodiment, the first semiconductor layer SCL1 and the second semiconductor layer SCL2 may have different lengths (or thicknesses) in the longitudinal direction of the light emitting element LD. For example, the first semiconductor layer SCL1 may have a longer length (or thicker thickness) than the second semiconductor layer SCL2 in the longitudinal direction of the light emitting element LD. Accordingly, the active layer ACT may be positioned closer to the first end EP1 (for example, a P-type end) than to the second end EP2 (for example, an N-type end).

The electrode layer ETL may be disposed on the second semiconductor layer SCL2. The electrode layer ETL may protect the second semiconductor layer SCL2 and may be an electrode for smoothly connecting the second semiconductor layer SCL2 to at least one circuit element, electrode, and/or line. For example, the electrode layer ETL may be an ohmic contact electrode or a Schottky contact electrode.

According to an embodiment, the electrode layer ETL may include a metal or a metal oxide. For example, the electrode layer ETL may include a metal such as chromium (Cr), titanium (Ti), aluminum (Al), gold (Au), nickel (Ni), and copper (Cu), or an oxide or alloy thereof. The electrode layer ETL may include a transparent conductive material such as ITO (Indium Tin Oxide), IZO (Indium Zinc Oxide), ITZO (Indium Tin Zinc Oxide), ZnO (Zinc Oxide), and In₂O₃ (Indium Oxide), or a mixture thereof. Various other conductive materials may be used to form the electrode layer ETL.

According to an embodiment, the electrode layer ETL may be substantially transparent. Accordingly, light generated from the light emitting element LD may pass through the electrode layer ETL and be emitted from the first end EP1 of the light emitting element LD.

The insulating film INF may be provided on the surface of the light emitting element LD to surround side surfaces of the first semiconductor layer SCL1, the active layer ACT, the second semiconductor layer SCL2, and the electrode layer ETL. Accordingly, electrical stability of the light emitting element LD can be secured, and short circuit defects through the light emitting element LD can be prevented.

The insulating film INF may expose the electrode layer ETL (or the second semiconductor layer SCL2) and the first semiconductor layer SCL1 (or another electrode layer provided on the second end EP2 of the light emitting element LD) at the first and second ends EP1 and EP2 of the light emitting element LD, respectively. For example, the insulating film INF may not be provided on two bottom surfaces (for example, the upper and lower surfaces of the light emitting element LD) corresponding to the first and second ends EP1 and EP2 of the light emitting element LD. Accordingly, an electrical signal (for example, a driving power source and/or a signal) may be applied to the light emitting element LD by connecting the first end EP1 and the second end EP2 of the light emitting element LD to at least one electrode, line, and/or conductive pattern, respectively.

As the insulating film INF is provided on the surface of the light emitting element LD, surface defects of the light emitting element LD can be minimized, and lifespan and efficiency can be improved. In case that light emitting elements LD are disposed adjacent to each other, it is possible to prevent short circuit defects between the light emitting elements LD.

In an embodiment of the disclosure, the light emitting element LD may be manufactured by a surface treatment process. For example, when multiple light emitting elements LD are mixed with a fluid solution (or ink) and supplied to each emission area (for example, an emission area of a pixel), surfaces of the light emitting elements LD may be treated using a hydrophobic material so that the light emitting elements LD may be uniformly dispersed in the solution without being aggregated.

The insulating film INF may include a transparent insulating material. Accordingly, the light generated in the active layer ACT may pass through the insulating film INF and may be emitted to outside of the light emitting element LD. For example, the insulating film INF may include an insulating material including at least one of silicon oxide (SiOx) (for example, SiO₂), silicon nitride (SiNx) (for example, Si₃N₄), aluminum oxide (AlxOy) (for example, Al₂O₃), and titanium oxide (TixOy) (for example, TiO₂), but the disclosure is not limited thereto.

The insulating film INF may be formed of a single layer or multiple layers. For example, the insulating film INF may be formed of a double film.

According to an embodiment, the insulating film INF may be partially etched (or removed) in a portion of at least one of the first end EP1 and the second end EP2 of the light emitting element LD. For example, the insulating film INF may be etched to have a rounded shape at the first end EP1 of the light emitting element LD, but the shape of the insulating film INF is not limited thereto.

According to an embodiment, the light emitting element LD may have a small size in a range of nanometers to micrometers. For example, the light emitting element LD may have a diameter D (or the width of the cross-section) and/or a length L in a range of nanometers to micrometers. For example, the light emitting element LD may have a diameter D and/or a length L in a range of several tens of nanometers to several tens of micrometers. However, the size of the light emitting element LD may be changed.

The structure, shape, size, and/or type of the light emitting element LD may be changed according to embodiments. For example, the structure, shape, size, and/or type of the light emitting element LD may be variously changed according to design conditions of a light emitting device using the light emitting element LD or required light emitting characteristics.

The light emitting device including the light emitting element LD may be used in various types of devices requiring a light source. For example, light emitting elements LD may be arranged in a pixel of a display device, and the light emitting elements LD may be used as a light source of the pixel. The light emitting element LD may also be used in other types of devices that require a light source, such as a lighting device.

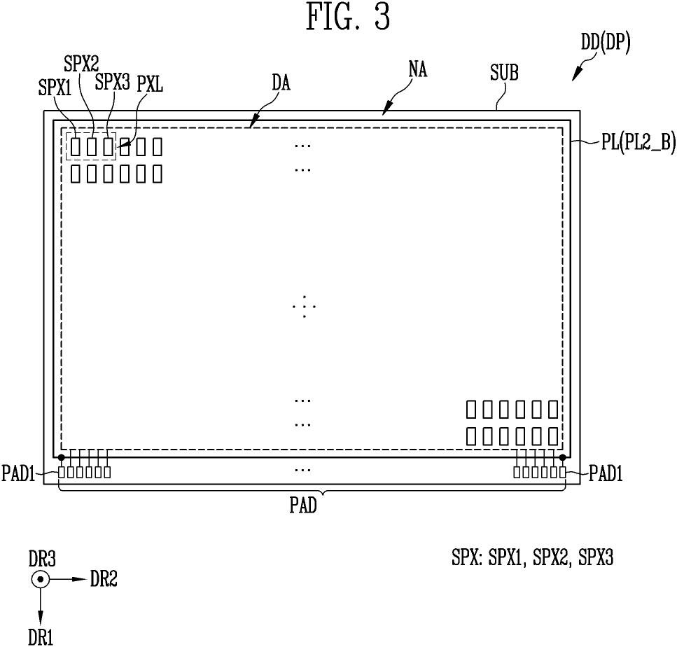

FIG. 3 is a plan view illustrating a display device DD according to an embodiment of the disclosure. FIG. 3 schematically shows a structure of the display device DD centered on a display panel DP including a display area DA. The display device DD may further include a driving circuit (for example, a driving circuit including a scan driver, a data driver, a timing controller, and the like) for driving pixels PXL. In an embodiment, at least a portion of the driving circuit may be formed and/or disposed inside of the display panel DP. In another embodiment, the driving circuit may be provided outside of the display panel DP.

Referring to FIGS. 1, 2 and 3, the display device DD may include a substrate SUB and pixels PXL provided on the substrate SUB.

The substrate SUB and the display device DD may include a display area DA for displaying an image and a non-display area NA located around the display area DA. The display area DA may be an area in which the pixels PXL are disposed, and may be an area in which an image is displayed by the pixels PXL. The non-display area NA may be an area other than the display area DA.

The substrate SUB and the display panel DP may be provided in various shapes. For example, the substrate SUB and the display device DD may be provided in the form of a plate having a substantially rectangular shape when viewed on a plane, and may include angled or rounded corners. The shapes of the substrate SUB and the display device DD may be changed. For example, the substrate SUB and the display device DD may have other polygonal shapes, such as a hexagon or an octagon, or a shape including a curved perimeter, such as a circle or an ellipse, when viewed on a plane.

In FIG. 3, according to an embodiment, the display device DD has a rectangular plate shape. Also, in the display device DD, a vertical direction (for example, a column direction) is indicated as a first direction DR1, a horizontal direction (for example, a row direction) is indicated as a second direction DR2, and a thickness direction (or a height direction) is indicated as a third direction DR3.

The display area DA may have various shapes. For example, the display area DA may have various shapes such as a rectangle, a circle, an oval, or the like. In an embodiment, the display area DA may have a shape corresponding to the shape of the display device DD.

The pixels PXL may be arranged in the display area DA. For example, the display area DA may include multiple pixel areas in which each pixel PXL is disposed.

According to an embodiment, each pixel PXL may include multiple sub-pixels SPX. For example, the pixel PXL may include a first sub-pixel SPX1, a second sub-pixel SPX2, and a third sub-pixel SPX3 adjacent to each other.

According to an embodiment, the first, second, and third sub-pixels SPX1, SPX2, and SPX3 may emit light of different colors. For example, the first, second, and third sub-pixels SPX1, SPX2, and SPX3 may emit blue, green, and red light, respectively. The number, type, and/or arrangement structure of the sub-pixels SPX constituting each pixel PXL may be variously changed according to embodiments.

Each sub-pixel SPX may include at least one light emitting element LD. For example, the sub-pixel SPX may include a light emitting unit including the light emitting element LD according to the embodiment of FIGS. 1 and 2, for example, a rod-like shape light emitting element LD having a small size in a range of nanometers to micrometers. The type, size, structure, and/or number of the light emitting elements LD provided in each sub-pixel SPX may be changed according to embodiments.

In an embodiment, the first sub-pixel SPX1, the second sub-pixel SPX2, and the third sub-pixel SPX3 may have a light emitting element LD of a first color, a light emitting element LD of a second color, and a light emitting element of a third color as light sources, respectively. Accordingly, the first sub-pixel SPX1, the second sub-pixel SPX2, and the third sub-pixel SPX3 may emit light of the first color, light of the second color, and light of the third color, respectively.

In another embodiment, the first sub-pixel SPX1, the second sub-pixel SPX2, and the third sub-pixel SPX3 may include light emitting elements LD emitting light of the same color. A light conversion layer including wavelength conversion particles (for example, particles that convert the color and/or wavelength of light, such as quantum dots QD) may be disposed in emission areas of the first sub-pixel SPX1, the second sub-pixel SPX2, and/or the third sub-pixel SPX3. Accordingly, the first sub-pixel SPX1, the second sub-pixel SPX2, and the third sub-pixel SPX3 may emit light of the first color, light of the second color, and light of the third color, respectively.

For example, the first sub-pixel SPX1, the second sub-pixel SPX2, and the third sub-pixel SPX3 may include blue light emitting elements, and a light conversion layer including wavelength conversion particles of the first color (for example, red quantum dots) may be disposed in the emission area of the first sub-pixel SPX1, and a light conversion layer including wavelength conversion particles of the second color (for example, green quantum dots) may be disposed in the emission area of the second sub-pixel SPX2. Accordingly, the first sub-pixel SPX1 may emit light of the first color (for example, red light), and the second sub-pixel SPX2 may emit light of the second color (for example, green light).

The sub-pixels SPX and the pixels PXL may have a structure according to at least one of embodiments described below. For example, the sub-pixels SPX and the pixels PXL may have a structure of the embodiments described below, or a structure with at least two embodiments combined.

Wirings, a built-in circuit unit, and/or pads PAD electrically connected to the pixels PXL of the display area DA may be disposed in the non-display area NA.

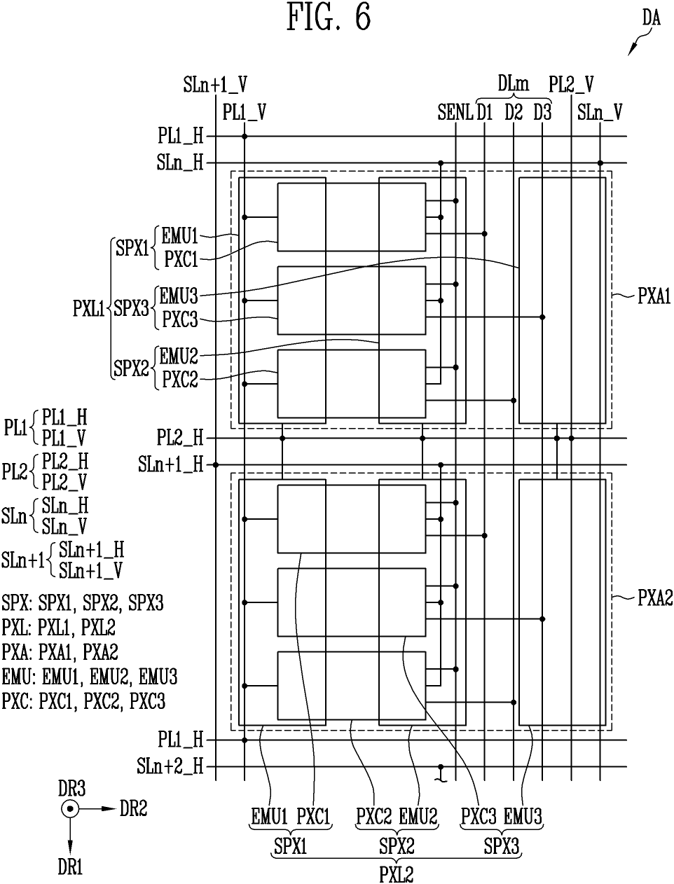

The wirings may include at least one power source line PL (for example, a bus line electrically connected to a power source line inside of the display area DA) for transmitting at least one pixel power to the pixels PXL. For example, the at least one power source line PL may include a second bus line PL2_B electrically connected to a second power source line PL2 (for example, a second power source line of FIG. 6) disposed in the display area DA to transmit a voltage of a second pixel power source to the pixels PXL. The at least one power source line PL may further include a first bus line electrically connected to a first power source line PL1 (for example, a first power source line of FIG. 6) disposed in the display area DA to transmit a voltage of a first pixel power source to the pixels PXL.

The pads PAD may include at least one power source pad electrically connected to the at least one power source line PL. For example, the pads PAD may include at least one first pad PAD1 electrically connected to the second bus line PL2_B (for example, multiple first pads PAD1 disposed on both lower edge areas of the display device DD). The pads PAD may further include at least one other power source pad connected to another power source line (for example, the first bus line) disposed in the non-display area NA, and/or signal pads connected to signal lines (for example, various signal lines connected to the pixels PXL, including scan lines and data lines) of the display area DA.

In an embodiment, the non-display area NA may have a narrow width. For example, the non-display area NA may have a width of about 100 µm or less. Accordingly, the display device DD may be implemented as a bezel-less display device.

In an embodiment, the wirings, the built-in circuit unit, and/or the pads PAD may be disposed only in a portion of the non-display area NA corresponding to any one of the outer sides of the display panel DP. For example, the display device DD may be a single side driving display device in which the wirings, the built-in circuit unit, and/or the pads PAD of the display panel DP are disposed only on one side of the non-display area NA located at the lower end (or upper end) of the display area DA, and wirings, a built-in circuit, and pads PAD are not disposed in the remaining non-display area NA of the display panel DP. An area of the non-display area NA may be reduced or minimized. When a tiled display device is configured using multiple display devices DD, a visibility of a boundary between adjacent display devices DD may be minimized or reduced. Accordingly, a seamless tiling display device may be implemented.

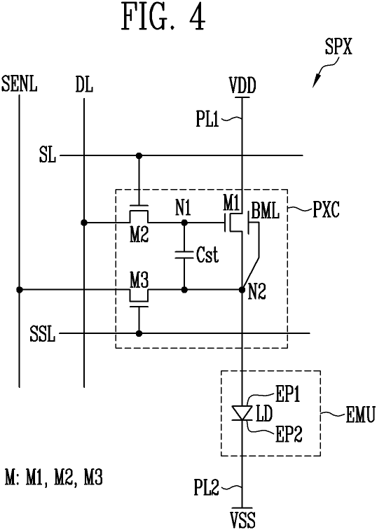

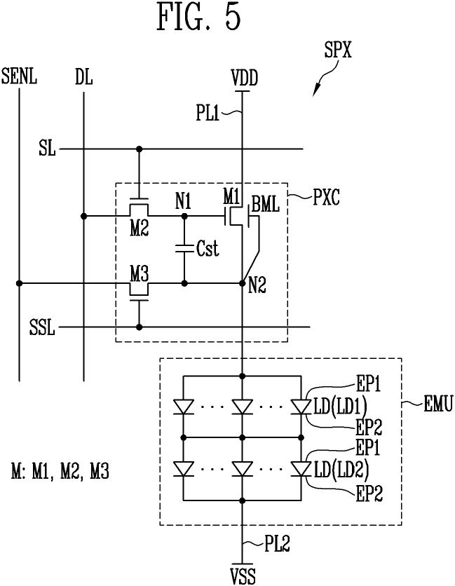

FIGS. 4 and 5 are circuit diagrams illustrating sub-pixels SPX according to embodiments of the disclosure. For example, FIGS. 4 and 5 show the sub-pixels SPX including light emitting units EMU having different structures.

Each of the sub-pixels SPX shown in FIGS. 4 or 5 may be any one of the sub-pixels SPX disposed in the display area DA of FIG. 3. The sub-pixels SPX may have substantially the same or similar structure.

Referring to FIGS. 4 and 5, a sub-pixel SPX may be connected to a scan line SL (also referred to as a first scan line), a data line DL, a first power source line PL1, and a second power source line PL2. Also, the sub-pixel SPX may be further connected to at least one other power source line and/or signal line. For example, the sub-pixel SPX may be further connected to a sensing line SENL (also referred to as an initialization power source line) and/or a control line SSL (also referred to as a second scan line).

The sub-pixel SPX may include a light emitting unit EMU for generating light having a luminance corresponding to each data signal. Also, the sub-pixel SPX may further include a pixel circuit PXC for driving the light emitting unit EMU.

The pixel circuit PXC may be connected to the scan line SL and the data line DL. Also, the pixel circuit PXC may be connected between the first power source line PL1 and the light emitting unit EMU. For example, the pixel circuit PXC may be electrically connected to the scan line SL to which a first scan signal is supplied, the data line DL to which a data signal is supplied, the first power source line PL1 to which a voltage of a first pixel power source VDD is applied, and the light emitting unit EMU.

The pixel circuit PXC may be further selectively connected to the control line SSL to which a second scan signal is supplied, and the sensing line SENL that is connected to a reference power source (or an initialization power source) or a sensing circuit in response to a display period or a sensing period. In an embodiment, the second scan signal may be the same as or different from the first scan signal. In case the second scan signal is the same as the first scan signal, the control line SSL may be integrated with the scan line SL.

The pixel circuit PXC may include at least one transistor M and a capacitor Cst. For example, the pixel circuit PXC may include a first transistor M1, a second transistor M2, a third transistor M3, and the capacitor Cst.

The first transistor M1 may be connected between the first power source line PL1 and a second node N2. The second node N2 may be a node to which the pixel circuit PXC and the light emitting unit EMU are connected. For example, the second node N2 may be a node to which one electrode (for example, a source electrode) of the first transistor M1 and the light emitting unit EMU are connected. A gate electrode of the first transistor M1 may be connected to a first node N1. The first transistor M1 may control driving current supplied to the light emitting unit EMU in response to a voltage from the first node N1. For example, the first transistor M1 may be a driving transistor of the sub-pixel SPX.

In an embodiment, the first transistor M1 may further include a bottom metal layer BML (also referred to as a back gate electrode or a second gate electrode). In an embodiment, the bottom metal layer BML may be connected to one electrode (for example, the source electrode) of the first transistor M1.

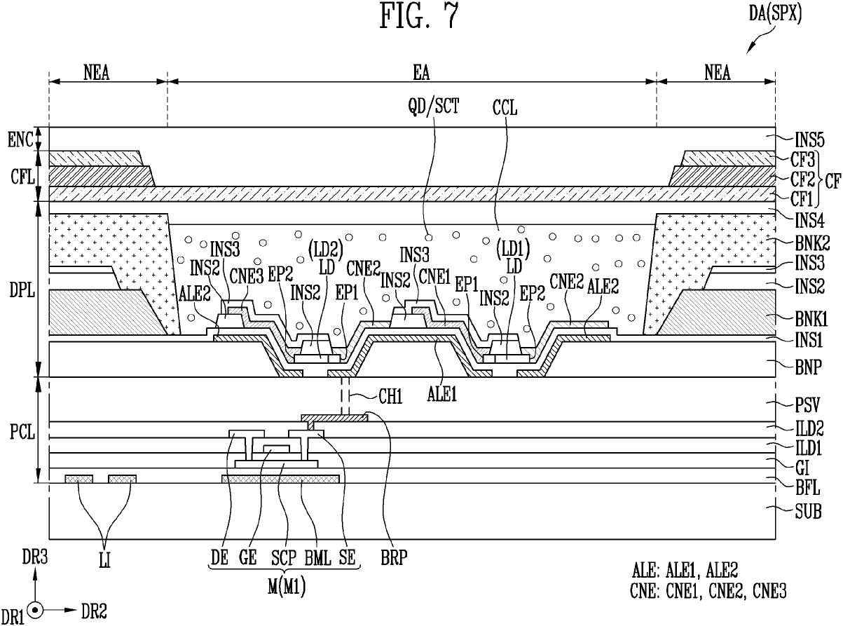

In an embodiment in which the first transistor M1 includes the bottom metal layer BML, a back-biasing technique (or a sync technique) in which a threshold voltage of the first transistor M1 is shifted in a negative direction or a positive direction by applying a back-biasing voltage to the bottom metal layer BML of the first transistor M1 may be applied. When the bottom metal layer BML is disposed under a semiconductor pattern (for example, a semiconductor pattern SCP of FIG. 7) constituting a channel of the first transistor M1, light incident on the semiconductor pattern may be blocked so that operating characteristics of the first transistor M1 may be stabilized.

The second transistor M2 may be connected between the data line DL and the first node N1. A gate electrode of the second transistor M2 may be connected to the scan line SL. The second transistor M2 may be turned on when the first scan signal of a gate-on voltage (for example, a logic high voltage or a high level voltage) is supplied from the scan line SL to connect the data line DL and the first node N1.

The data signal of a corresponding frame may be supplied to the data line DL for each frame period, and the data signal may be transferred to the first node N1 through the second transistor M2 during a period in which the first scan signal of the gate-on voltage is supplied. For example, the second transistor M2 may be a switching transistor for transferring each data signal to the sub-pixel SPX.

The capacitor Cst may be connected between the first node N1 and the second node N2. The capacitor Cst may charge a voltage corresponding to the data signal supplied to the first node N1 during each frame period.

The third transistor M3 may be connected between the second node N2 and the sensing line SENL. A gate electrode of the third transistor M3 may be connected to the control line SSL (or the scan line SL). The third transistor M3 may be turned on when the second scan signal (or the first scan signal) of the gate-on voltage (for example, the logic high voltage or the high level voltage) is supplied from the control line SSL to transfer a reference voltage (or an initialization voltage) supplied to the sensing line SENL to the second node N2 or a voltage of the second node N2 to the sensing line SENL. In an embodiment, the voltage of the second node N2 may be transferred to the sensing circuit through the sensing line SENL, and may be provided to the driving circuit (for example, the timing controller) and used to compensate a deviation in characteristics of the sub-pixels SPX.

Although all of transistors M included in the pixel circuit PXC are shown as N-type transistors in FIGS. 4 and 5, embodiments of the disclosure are not limited thereto. For example, at least one of the first, second, and third transistors M1, M2, and M3 may be changed to a P-type transistor. The structure and driving method of the sub-pixel SPX may be variously changed according to embodiments.

The light emitting unit EMU may include at least one light emitting element LD connected between the first pixel power source VDD and a second pixel power source VSS. For example, the light emitting unit EMU may include at least one light emitting element LD including the first end EP1 electrically connected to the first pixel power source VDD through the pixel circuit PXC and the first power source line PL1, and the second end EP2 electrically connected to the second pixel power source VSS through the second power source line PL2.

According to an embodiment, the first pixel power source VDD may be a high potential pixel power source, and the second pixel power source VSS may be a low potential pixel power source. A potential difference between the first pixel power source VDD and the second pixel power source VSS may be equal to or greater than a threshold voltage of the light emitting elements LD.

According to an embodiment, the first end EP1 may be the P-type end of the light emitting element LD, and the second end EP2 may be the N-type end of the light emitting element LD. For example, the light emitting element LD may be electrically connected between the first pixel power source VDD and the second pixel power source VSS in a forward direction.

At least one light emitting element LD connected in a forward direction between the first pixel power source VDD and the second pixel power source VSS may constitute an effective light source of a corresponding sub-pixel SPX. For example, at least one light emitting element LD connected in a forward direction between the first pixel power source VDD and the second pixel power source VSS may emit light with a luminance corresponding to the driving current supplied from the pixel circuit PXC during each frame period.

In an embodiment, as shown in FIG. 4, the light emitting unit EMU may include a single light emitting element LD connected in a forward direction between the first pixel power source VDD and the second pixel power source VSS. In another embodiment, the light emitting unit EMU may include multiple light emitting elements LD connected in a forward direction between the first pixel power source VDD and the second pixel power source VSS. For example, as shown in FIG. 5, the light emitting unit EMU may include light emitting elements LD connected in series and parallel between the first pixel power source VDD and the second pixel power source VSS. For example, the light emitting unit EMU may include first and second series stages, and may include at least one first light emitting element LD1 disposed and/or connected to the first series stage and at least one second light emitting element LD2 disposed and/or connected to the second series stage. A connection structure of the light emitting elements LD constituting each light emitting unit EMU may be changed according to embodiments. For example, multiple light emitting elements LD may be connected only in series or in parallel between the first pixel power source VDD and the second pixel power source VSS. The number, type, and/or connection structure of the light emitting element(s) LD constituting the effective light source of the sub-pixel SPX may be variously changed according to embodiments.

According to an embodiment, each light emitting element LD may be a rod-shaped inorganic light emitting element. Each light emitting element LD may be an ultra-small light emitting element having a size in a range of nanometers to micrometers. However, the type, material, structure, size, and/or shape of the light emitting element LD may be variously changed according to embodiments.

FIG. 6 is a plan view illustrating a display area DA according to an embodiment of the disclosure. FIG. 6 schematically shows a structure of the display area DA centered on a first pixel PXL1 and a second pixel PXL2 sequentially arranged in the display area DA along a first direction DR1. For example, the first pixel PXL1 may be disposed on an n-th horizontal line (for example, an n-th pixel row) and an m-th vertical line (for example, an m-th pixel column) of the display area DA, and the second pixel PXL2 may be disposed on an (n+1)th horizontal line (for example, an (n+1)th pixel row) and the m-th vertical line of the display area DA, where n and m may be natural numbers. That is, the first pixel PXL1 and the second pixel PXL2 may be disposed on the same vertical line in the display area DA and may be vertically adjacent to each other in the first direction DR1.

Referring to FIGS. 3 to 6, the display area DA may include multiple pixels PXL including the first pixel PXL1 and the second pixel PXL2, and scan lines SL, data lines DL, sensing lines SENL, a first power source line PL1, and a second power source line PL2 connected to the pixels PXL. In an embodiment, a control line SSL of each horizontal line may be integrated with a scan line SL of a corresponding horizontal line, but the disclosure is not limited thereto.

The scan lines SL may be formed for each horizontal line. Each scan line SL may be connected to pixel circuits PXC of sub-pixels SPX disposed on the corresponding horizontal line.

In an embodiment, each scan line SL may include sub-scan lines extending in the first direction DR1 and a second direction DR2, respectively, in the display area DA. For example, an n-th scan line SLn may include a first sub-scan line SLn_H disposed on the n-th horizontal line of the display area DA and extending along the second direction DR2, and a second sub-scan line SLn_V extending along the first direction DR1 in the display area DA to intersect the first sub-scan line SLn_H and connected to the first sub-scan line SLn_H. Similarly, an (n+1)th scan line SLn+1 may include a first sub-scan line SLn+1_H disposed on the (n+1)th horizontal line of the display area DA and extending along the second direction DR2, and a second sub-scan line SLn+1_V extending along the first direction DR1 in the display area DA to intersect the first sub-scan line SLn+1_H and connected to the first sub-scan line SLn+1_H.

In case that the scan lines SL are formed of a mesh-shaped wiring, positions of the pads PAD and/or the driving circuit (for example, the scan driver) may be freely changed. For example, even when the display device DD is a single side driving display device, each scan signal may be supplied to the pixels PXL in horizontal lines.

The data lines DL may extend along the first direction DR1 in the display area DA and may be formed for each vertical line. However, the disclosure is not limited thereto. For example, the data lines DL may be formed for every two adjacent vertical lines, and the two vertical lines may share the data lines DL. By separating the scan lines SL connected to the pixels PXL of the two vertical lines, the time at which the data signal is sent to the pixels PXL can be separated.

Each data line DL may be connected to the pixel circuits PXC of the sub-pixels SPX disposed on a corresponding vertical line. Each data line DL may include multiple sub-data lines respectively connected to the sub-pixels SPX constituting each pixel PXL. For example, an m-th data line DLm may include a first sub-data line D1 connected to first sub-pixels SPX1 of the pixels PXL disposed on the m-th vertical line, a second sub-data line D2 connected to second sub-pixels SPX2 of the pixels PXL disposed on the m-th vertical line, and a third sub-data line D3 connected to third sub-pixels SPX3 of the pixels PXL disposed on the m-th vertical line. Accordingly, the data signal may be respectively supplied to each sub-pixel SPX.

The sensing lines SENL may extend along the first direction DR1 in the display area DA and may be formed for at least one vertical line. In an embodiment, the sensing lines SENL may be formed for each vertical line and may be commonly connected to the sub-pixels SPX constituting each pixel PXL. Characteristics of each pixel PXL can be individually detected. In another embodiment, the sensing lines SENL may be formed to be shared by multiple vertical lines. Characteristics of the pixels PXL can be detected in units of blocks including multiple pixels PXL.

The first power source line PL1 and the second power source line PL2 may be commonly connected to the pixels PXL of the display area DA. For example, the first power source line PL1 may be commonly connected to the pixel circuits PXC of the sub-pixels SPX, and the second power source line PL2 may be commonly connected to the light emitting units EMU of the sub-pixels SPX.

In an embodiment, the first power source line PL1 may be connected to a first bus line disposed in the non-display area NA, and may be connected to at least one pad PAD through the first bus line. In an embodiment, the second power source line PL2 may be connected to a second bus line PL2_B disposed in the non-display area NA, and may be connected to at least one pad PAD (for example, at least one first pad PAD1) through the second bus line PL2_B.

According to an embodiment, each of the first power source line PL1 and the second power source line PL2 may be formed of a mesh-shaped wiring. Therefore, voltage drop (IR drop) of the first power source VDD and the second power source VSS may be prevented or minimized, and the first power source VDD and the second power source VSS having a uniform level may be transmitted to the pixels PXL.

For example, the first power source line PL1 may include at least one (1-1)th sub-power source line PL1_V extending in the first direction DR1 in the display area DA, and at least one (1-2)th sub-power source line PL1_H extending in the second direction DR2 in the display area DA and connected to the (1-1)th sub-power source line PL1_V. The (1-1)th sub-power source line PL1_V and the (1-2)th sub-power source line PL1_H may cross each other, and may be connected to each other at all or some of crossing points.

Similarly, the second power source line PL2 may include at least one (2-1)th sub-power source line PL2_V extending in the first direction DR1 in the display area DA, and at least one (2-2)th sub-power source line PL2_H extending in the second direction DR2 in the display area DA and connected to the (2-1)th sub-power source line PL2_V. The (2-1)th sub-power source line PL2_V and the (2-2)th sub-power source line PL2_H may cross each other, and may be connected to each other at all or some of crossing points.

In an embodiment, the (1-1)th sub-power source line PL1_V and the (2-1)th sub-power source line PL2_V may be formed for at least one vertical line. For example, the (1-1)th sub-power source line PL1_V and the (2-1)th sub-power source line PL2_V may be formed for each vertical line, and may be spaced apart from each other with the pixel circuits PXC arranged in a pixel column of a corresponding vertical line interposed therebetween. The number and/or positions of the (1-1)th sub-power source line PL1_V and the (2-1)th sub-power source line PL2_V may be variously changed according to embodiments.

In an embodiment, the (1-2)th sub-power source line PL1_H and the (2-2)th sub-power source line PL2_H may be formed for one horizontal line or for each of multiple horizontal lines. For example, the (1-2)th sub-power source line PL1_H and the (2-2)th sub-power source line PL2_H may be alternately arranged along the first direction DR1 in the display area DA with pixels PXL disposed on each vertical line interposed therebetween. For example, the (1-2)th sub-power source line PL1_H may be positioned in an upper area of a pixel row positioned on an odd-numbered horizontal line, and the (2-2)th sub-power source line PL2_H may be positioned in an upper area of a pixel row positioned on an even-numbered horizontal line. A pair of the (1-2)th sub-power source line PL1_H and the (2-2)th sub-power line PL2_H adjacent to each other may be spaced apart from each other with the pixel circuits PXC arranged in a pixel row of each horizontal line interposed therebetween. The number and/or positions of the (1-2)th sub-power source line PL1_H and the (2-2)th sub-power source line PL2_H may be variously changed according to embodiments.

Each pixel PXL may include multiple sub-pixels SPX. For example, each pixel PXL may include the first sub-pixel SPX1, the second sub-pixel SPX2, and the third sub-pixel SPX3.

Each sub-pixel SPX may include the pixel circuit PXC and the light emitting unit EMU. For example, the first sub-pixel SPX1 may include a first pixel circuit PXC1 and a first light emitting unit EMU1, the second sub-pixel SPX2 may include a second pixel circuit PXC2 and a second light emitting unit EMU2, and the third sub-pixel SPX3 may include a third pixel circuit PXC3 and a third light emitting unit EMU3.

The pixel circuits PXC and the light emitting units EMU of each pixel PXL may be disposed on different layers and may overlap each other. For example, the pixel circuits PXC may be disposed in a pixel circuit layer (for example, a circuit layer PCL of FIG. 7) of a pixel area PXA in which each pixel PXL is disposed. The light emitting units EMU may be disposed in a display layer (for example, a display layer DPL of FIG. 7) of each pixel area PXA to overlap the pixel circuits PXC of a corresponding pixel PXL and/or at least one wiring (for example, at least one scan line SL, sensing line SENL, data line DL, first power source line PL1, and/or second power source line PL2).

The first, second, and third pixel circuits PXC1, PXC2, and PXC3 may be arranged along the first direction DR1 in each pixel area PXA. For example, the first, second, and third pixel circuits PXC1, PXC2, and PXC3 of the first pixel PXL1 may be arranged in a predetermined order along the first direction DR1 in a first pixel area PXA1 in which the first pixel PXL1 is provided. Similarly, the first, second, and third pixel circuits PXC1, PXC2, and PXC3 of the second pixel PXL2 may be arranged in a predetermined order along the first direction DR1 in a second pixel area PXA2 in which the second pixel PXL2 is provided.

In an embodiment, the third pixel circuit PXC3 may be positioned at a central portion of each pixel area PXA in the first direction DR1, and the first and second pixel circuits PXC1 and PXC2 may be disposed on both sides of the third pixel circuit PXC3 in the first direction DR1. However, positions and/or arrangement order of the first, second, and third pixel circuits PXC1, PCX2, and PCX3 may be changed according to embodiments.

The first, second, and third pixel circuits PXC1, PXC2, and PXC3 may be commonly connected to the first power source line PL1 and the scan line SL of a corresponding horizontal line, and may be connected to different sub-data lines of a corresponding vertical line. For example, the first pixel circuit PXC1 may be connected to the first sub-data line D1, the second pixel circuit PXC2 may be connected to the second sub-data line D2, and the third pixel circuit PXC3 may be connected to the third sub-data line D3.

In an embodiment, the first, second, and third pixel circuits PXC1, PXC2, and PXC3 may be further connected to the sensing line SENL. For example, the first, second, and third pixel circuits PXC1, PXC2, and PXC3 may be commonly connected to the sensing line SENL of the corresponding vertical line.

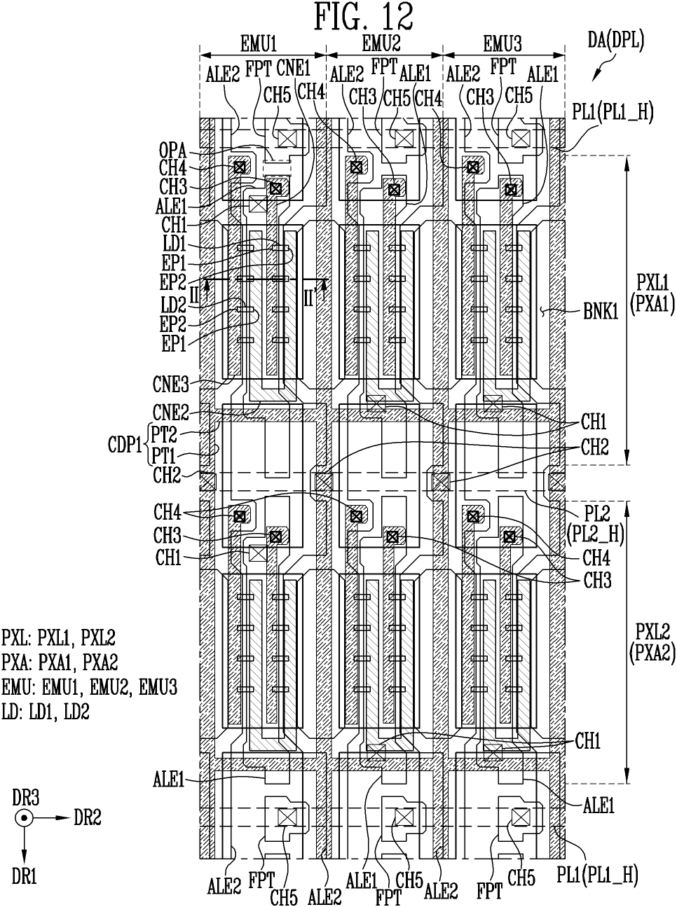

The first, second, and third light emitting units EMU1, EMU2, and EMU3 may be connected between each pixel circuit PXC and the second power source line PL2. For example, the first, second, and third light emitting units EMU1, EMU2, and EMU3 may be electrically connected to the first, second, and third pixel circuits PXC1, PXC2, and PXC3 through each first contact hole (for example, a first contact hole CH1 of FIG. 7 and/or FIG. 12), respectively. The first, second, and third light emitting units EMU1, EMU2, and EMU3 may be electrically connected to the second power source line PL2 through each second contact hole (for example, a second contact hole CH2 of FIG. 12), respectively.

The first, second, and third light emitting units EMU1, EMU2, and EMU3 may be arranged along the second direction DR1 in each pixel area PXA. For example, the first, second, and third light emitting units EMU1, EMU2, and EMU3 of the first pixel PXL1 may be sequentially arranged along the second direction DR2 in the first pixel area PXA1 in which the first pixel PXL1 is provided. Similarly, the first, second, and third light emitting units EMU1, EMU2, and EMU3 of the second pixel PXL2 may be sequentially arranged along the second direction DR2 in the second pixel area PXA2 in which the second pixel PXL2 is provided. The first, second, and third sub-pixels SPX1, SPX2, and SPX3 may have emission areas corresponding to an area (or a portion) of the first, second, and third light emitting units EMU1, EMU2, and EMU3, respectively. Accordingly, the emission areas of the first, second, and third sub-pixels SPX1, SPX2, and SPX3 may be sequentially arranged along the second direction DR2. Based on the emission areas of the first, second, and third sub-pixels SPX1, SPX2, and SPX3, the first, second, and third sub-pixels SPX1, SPX2, and SPX3 may be viewed as being arranged in the second direction DR2.

The first, second, and third light emitting units EMU1, EMU2, and EMU3 may or may not overlap with at least one signal line and/or at least one power source line. For example, the third light emitting unit EMU3 of each pixel PXL may overlap the third sub-data line D3, the (2-1)th sub-power source line PL2_V, and/or the second sub-scan line SLn_V of the corresponding vertical line.

FIG. 6 shows an embodiment in which the pixel circuits PXC and the light emitting units EMU of the sub-pixels SPX are arranged along different directions in each pixel area PXA, but the disclosure is not limited thereto. For example, positions and/or arrangement direction of the pixel circuits PXC and the light emitting units EMU may be variously changed according to embodiments.

FIG. 7 is a schematic cross-sectional view illustrating the display area DA according to an embodiment of the disclosure. For example, FIG. 7 schematically shows a cross-section of the display area DA centered on one sub-pixel SPX including the light emitting unit EMU having a series and parallel structure including the first and second light emitting elements LD1 and LD2 as in the embodiment of FIG. 5.

The sub-pixels SPX disposed in the display area DA may have substantially the same or similar cross-sectional structure. However, the size, position, and/or shape of circuit elements constituting the sub-pixels SPX and electrodes included in the circuit elements may be different for each sub-pixel SPX. For example, when viewed on a plane, the first transistor M1 of the first sub-pixel SPX1 may have a shape different from that of the first transistor M1 of the second sub-pixel SPX2.

Referring to FIGS. 1 to 7, the display device DD may include a substrate SUB, a circuit layer PCL (also referred to as a pixel circuit layer), and a display layer DPL (also referred to as a display element layer). The circuit layer PCL and the display layer DPL may be provided to overlap each other on the substrate SUB. For example, the circuit layer PCL and the display layer DPL may be sequentially disposed on one surface of the substrate SUB.

The display device DD may further include a color filter layer CFL and/or an encapsulation layer ENC (or a protective layer) disposed on the display layer DPL. In an embodiment, the color filter layer CFL and the encapsulation layer ENC may be disposed above a surface of the substrate SUB where the circuit layer PCL and the display layer DPL are disposed. Accordingly, the thickness of the display device DD can be reduced.

The substrate SUB may be a substrate or a film made of a rigid or flexible material. In an embodiment, the substrate SUB may include at least one insulating material and may have a single-layer or multi-layer structure.

The circuit layer PCL may be provided on one surface of the substrate SUB. The circuit layer PCL may include the pixel circuits PXC of each pixel PXL. For example, in each pixel area PXA of the circuit layer PCL, circuit elements (for example, transistors M and capacitors Cst) constituting the first, second, and third pixel circuits PXC1, PXC2, and PXC3 may be formed. In FIG. 7, as an example of the circuit elements that may be disposed in the circuit layer PCL of the display area DA, a cross-section of any one transistor M (for example, the first transistor M1 including the bottom metal layer BML) included in each pixel circuit PXC is schematically shown.

The circuit layer PCL may include signal lines and power source lines connected to the pixels PXL. For example, the circuit layer PCL may include the scan lines SL, the data lines DL, the sensing lines SENL, and the first and second power source lines PL1 and PL2. Also, the circuit layer PCL may further include at least one power source line PL disposed in the non-display area NA. For example, the second bus line PL2_B of FIG. 3 may be disposed in the non-display area NA of the circuit layer PCL, and the second bus line PL2_B of FIG. 3 may be electrically connected to the second power source line PL2 disposed in the display area DA.

In FIG. 7, for example, wirings may be disposed in the circuit layer PCL. The wirings LI may be disposed in the display area DA. The wirings LI and the bottom metal layer BML may be disposed on a same layer. Each wiring LI may be at least one of signal lines and power source lines connected to the sub-pixels SPX. According to an embodiment, at least one signal line and/or power source line may be disposed in another layer of the circuit layer PCL.

The circuit layer PCL may further include multiple insulating layers. For example, the circuit layer PCL may include a buffer layer BFL, a gate insulating layer GI, a first interlayer insulating layer ILD1, a second interlayer insulating layer ILD2, and/or a passivation layer PSV sequentially disposed on one surface of the substrate SUB.

The circuit layer PCL may include a first conductive layer disposed on the substrate SUB and including bottom metal layers BML of first transistors M1. For example, the first conductive layer may be disposed between the substrate SUB and the buffer layer BFL and may include the bottom metal layers BML of the first transistors M1 included in the sub-pixels SPX. Each bottom metal layer BML may overlap the semiconductor pattern SCP of the first transistor M1 corresponding thereto.

The first conductive layer may further include at least one wiring LI. For example, the first conductive layer may include at least some of the wirings extending in the first direction DR1 in the display area DA. For example, the first conductive layer may include second sub-scan lines (for example, second sub-scan lines SLn_V and SLn+1_V of the n-th scan line SLn and the (n+1)th scan line SLn+1 of FIG. 6), the (1-1)th sub-power source lines PL1_V, the sensing lines SENL, the data lines DL, and the (2-1)th sub-power source lines PL2_V.

The buffer layer BFL may be disposed on one surface of the substrate SUB including the first conductive layer. The buffer layer BFL may prevent impurities from diffusing into each circuit element.

A semiconductor layer may be disposed on the buffer layer BFL. The semiconductor layer may include semiconductor patterns SCP of the transistors M. Each semiconductor pattern SCP may include a channel region overlapping a gate electrode GE of a corresponding transistor M, and first and second conductive regions (for example, source and drain regions) disposed on both sides of the channel region.

The gate insulating layer GI may be disposed on the semiconductor layer. A second conductive layer may be disposed on the gate insulating layer GI.

The second conductive layer may include gate electrodes GE of the transistors M. The second conductive layer may further include one electrode of each of the capacitors Cst provided in the pixel circuits PXC and/or bridge patterns. When at least one power source line and/or signal line (for example, the second sub-scan lines) disposed in the display area DA is composed of multiple layers, the second conductive layer may further include at least one conductive pattern constituting the at least one power source line and/or signal line.

The first interlayer insulating layer ILD1 may be disposed on the second conductive layer. A third conductive layer may be disposed on the first interlayer insulating layer ILD1.

The third conductive layer may include source electrodes SE and drain electrodes DE of the transistors M. Each source electrode SE may be connected to one region (for example, the source region) of the semiconductor pattern SCP included in a corresponding transistor M through at least one contact hole, and each drain electrode DE may be connected to another region (for example, the drain region) of the semiconductor pattern SCP included in the corresponding transistor M through at least one other contact hole.

The third conductive layer may further include one electrode of each of the capacitors Cst provided in the pixel circuits PXC, predetermined wirings, and/or bridge patterns. For example, the third conductive layer may include at least one of the wirings extending in the second direction DR2 in the display area DA. In an embodiment, the third conductive layer may include first sub-scan lines (for example, first sub-scan lines SLn_H, SLn+1_H, and SLn+2_H, (1-2)th sub-power source lines PL1_H, and (2-2)th sub-power source lines PL2_H of the n-th scan line SLn, the (n+1)th scan line SLn+1, and the (n+2)th scan line SLn+2 of FIG. 6). In case at least one power source line and/or signal line (for example, the second sub-scan lines) disposed in the display area DA is composed of multiple layers, the third conductive layer may further include at least one conductive pattern constituting the at least one power source line and/or signal line.

In an embodiment, the circuit layer PCL may further include the second interlayer insulating layer ILD2 and a fourth conductive layer disposed on the third conductive layer. For example, the second interlayer insulating layer ILD2 may be disposed on the third conductive layer, and the fourth conductive layer may be disposed on the second interlayer insulating layer ILD2.

The fourth conductive layer may include at least one bridge pattern and/or wiring. For example, the fourth conductive layer may include at least one circuit element (for example, the first transistor M1) provided in the pixel circuit PXC of each sub-pixel SPX, and each bridge pattern BRP for electrically connecting first alignment electrodes ALE1 provided in the light emitting unit EMU of the sub-pixel SPX. For example, each bridge pattern BRP may be electrically connected to the source electrode SE of the first transistor M1 through a contact hole penetrating the second interlayer insulating layer ILD2. Each bridge pattern BRP may be electrically connected to the first alignment electrode ALE1 provided in the light emitting unit EMU of a corresponding sub-pixel SPX through each first contact hole CH1 formed in the passivation layer PSV. FIG. 7 schematically shows the first contact hole CH1 positioned inside the emission area EA to show a connection between the pixel circuit PXC and the light emitting unit EMU, but the position of the first contact hole CH1 may be changed according to the structure and/or relative position of the pixel circuit PXC and the light emitting unit EMU. For example, the first contact hole CH1 may be disposed in a non-emission area NEA to overlap a first bank BNK1.

In an embodiment, the fourth conductive layer may further include at least one wiring disposed in the non-display area NA. For example, the fourth conductive layer may include the second bus line PL2_B disposed in the non-display area NA.

Each electrode, conductive pattern, and/or wiring constituting the first to fourth conductive layers may have conductivity by including at least one conductive material, and materials constituting them are not particularly limited. For example, each electrode, conductive pattern, and/or wiring constituting the first to fourth conductive layers may include at least one metal selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), titanium (Ti), tantalum (Ta), tungsten (W), and copper (Cu), or may include other conductive materials.

The passivation layer PSV may be disposed on the fourth conductive layer. Each of the buffer layer BFL, the gate insulating layer GI, the first interlayer insulating layer ILD1, the second interlayer insulating layer ILD2, and the passivation layer PSV may be composed of a single layer or multiple layers, and may include at least one inorganic insulating material and/or organic insulating material. For example, each of the buffer layer BFL, the gate insulating layer GI, the first interlayer insulating layer ILD1, the second interlayer insulating layer ILD2, and the passivation layer PSV may include various types of organic/inorganic insulating materials such as silicon nitride (SiNx), silicon oxide (SiOx), or oxynitride (SiOxNy). In an embodiment, the passivation layer PSV may include an organic insulating layer and may planarize the surface of the circuit layer PCL.

The display layer DPL may be disposed on the passivation layer PSV.

The display layer DPL may include the light emitting units EMU of each pixel PXL. For example, the light emitting elements LD constituting the first, second, and third light emitting units EMU1, EMU2, and EMU3 and pixel electrodes connected thereto (for example, at least one pair of alignment electrodes ALE and at least one pair of contact electrodes CNE provided in each light emitting unit EMU) may be formed in each pixel area PXA of the display layer DPL.

FIG. 7 shows a schematic cross-section of the light emitting unit EMU including the first light emitting element LD1 and the second light emitting element LD2 as in the embodiment of FIG. 5 of the light emitting unit EMU that may be disposed in the display layer DPL of the display area DA. For example, the display layer DPL may include the first and second alignment electrodes ALE1 and ALE2, the first and second light emitting elements LD1 and LD2, and first, second, and third contact electrodes CNE1, CNE2, and CNE3 which are disposed in the emission area EA of each sub-pixel SPX to configure the light emitting unit EMU of the corresponding sub-pixel SPX.

Also, the display layer DPL may further include insulating layers and/or insulating patterns sequentially disposed on one surface of the substrate SUB on which the circuit layer PCL is formed. For example, the display layer DPL may include bank patterns BNP, a first insulating layer INS1, a first bank BNK1, a second insulating layer INS2, a third insulating layer INS3, and a fourth insulating layer INS4 which are sequentially disposed on the circuit layer PCL. Also, the display layer DPL may selectively further include a second bank BNK2 and a light conversion layer CCL.

The bank patterns BNP (also referred to as patterns or wall patterns) may be provided and/or formed on the passivation layer PSV. In an embodiment, the bank patterns BNP may be formed as separated patterns that are individually disposed under the alignment electrodes ALE to overlap a portion of each of the alignment electrodes ALE. Alternatively, the bank patterns BNP may have openings or concave portions corresponding to areas between the alignment electrodes ALE (for example, areas in which the light emitting elements are arranged) in the emission areas EA of the sub-pixels SPX, and may be formed as an integrated pattern connected to each other in the entire display area DA.

The alignment electrodes ALE may protrude upward (for example, the third direction DR3) from the periphery of the light emitting elements LD by the bank patterns BNP. The bank patterns BNP and the alignment electrodes ALE may form a reflective protrusion pattern around the light emitting elements LD. Accordingly, luminous efficiency of the sub-pixels SPX may be improved.

The bank patterns BNP may include an inorganic insulating material and/or an organic insulating material, and may have a single-layer or multi-layer structure. The alignment electrodes ALE (for example, the first and second alignment electrodes ALE1 and ALE2) of the light emitting units EMU may be formed on the bank patterns BNP.

The alignment electrodes ALE may include at least one conductive material, and the material constituting the alignment electrode ALE is not particularly limited. For example, the alignment electrodes ALE may include various metals such as at least one of silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), or an alloy thereof, a conductive oxide such as ITO (Indium Tin Oxide), IZO (Indium Zinc Oxide), ITZO (Indium Tin Zinc Oxide), ZnO (Zinc Oxide), AZO (Aluminum doped Zinc Oxide), GZO (Gallium doped Zinc Oxide), ZTO (Zinc Tin Oxide), GTO (Gallium Tin Oxide), or FTO (Fluorine doped Tin Oxide), and a conductive polymer such as PEDOT. Alternatively, the alignment electrodes ALE may include carbon nanotubes, graphene, or other conductive materials.

In an embodiment, at least one first alignment electrode ALE1 and at least one second alignment electrode ALE2 may be disposed in the emission area EA of each of the sub-pixels SPX. For example, one first alignment electrode ALE1 may be disposed in a central portion of the emission area EA, and two second alignment electrodes ALE2 may be disposed on both sides of the first alignment electrode ALE1. The second alignment electrodes ALE2 may be integrally or non-integrally connected with each other, and may be supplied with the same signal or power source. The number, the shape, size, and/or position of the first and second alignment electrodes ALE1 and ALE2 disposed in each emission area EA may be variously changed according to embodiments.

Each of the first and second alignment electrodes ALE1 and ALE2 may be composed of a single layer or multiple layers. For example, the first and second alignment electrodes ALE1 and ALE2 may include a reflective electrode layer including a reflective conductive material (for example, metal), and may be configured as a single-layer or multi-layer electrode.

The first insulating layer INS1 may be disposed on the first and second alignment electrodes ALE1 and ALE2. In an embodiment, the first insulating layer INS1 may include contact holes (for example, third and fourth contact holes CH4 of FIG. 12) for connecting the first and second alignment electrodes ALE1 and ALE2 to different contact electrodes CNE (for example, the first and third contact electrodes CNE1 and CNE3).

The first insulating layer INS1 may be composed of a single layer or multiple layers, and may include at least one inorganic insulating material and/or organic insulating material. In an embodiment, the first insulating layer INS1 may include at least one type of inorganic insulating material such as silicon nitride (SiNx), silicon oxide (SiOx), or silicon oxynitride (SiOxNy).

Since the first and second alignment electrodes ALE1 and ALE2 are covered by the first insulating layer INS1, damage to the first and second alignment electrodes ALE1 and ALE2 may be prevented in a subsequent process. Short circuit defects in which the first and second alignment electrodes ALE1 and ALE2 and the light emitting elements LD are unintentionally connected may be prevented.

The first bank BNK1 may be disposed in the display area DA in which the first and second alignment electrodes ALE1 and ALE2 and the first insulating layer INS1 are formed. The first bank BNK1 may have openings in the emission areas EA of the sub-pixels SPX, and may be formed in the non-emission area NEA to surround the emission areas EA of the sub-pixels SPX. Accordingly, each emission area EA to which the light emitting elements LD are to be provided may be defined (or partitioned). In an embodiment, the first bank BNK1 may include a light blocking and/or reflective material such as a black matrix material.

The light emitting elements LD may be supplied to each emission area EA surrounded by the first bank BNK1. The light emitting elements LD may be aligned between the first and second alignment electrodes ALE1 and ALE2 by first and second alignment signals applied to each first alignment electrode ALE1 (or a first alignment line before being separated into the first alignment electrode ALE1 of each of the sub-pixels SPX) and each second alignment electrode ALE2 (or a second alignment line before being separated into the second alignment electrode ALE2 of each of the sub-pixels SPX). For example, the light emitting elements LD supplied to each emission area EA may be arranged in the second direction DR2 or in a diagonal direction such that first ends EP1 face the first alignment electrode ALE1 and second ends EP2 face the second alignment electrodes ALE2.

The second insulating layer INS2 may be disposed on a portion of the light emitting elements LD. In an embodiment, the second insulating layer INS2 may be locally disposed only on a portion including a central portion of the light emitting elements LD so that the first and second ends EP1 and EP2 of the light emitting elements LD aligned in the emission area EA of a corresponding sub-pixel SPX are exposed. In another embodiment, the second insulating layer INS2 may be formed in the entire display area DA including multiple pixel areas, and areas corresponding to the first end EP1 and the second end EP2 of each of the light emitting elements LD may be partially opened as necessary. When the second insulating layer INS2 is formed on the light emitting elements LD, the light emitting elements LD can be stably fixed.

The second insulating layer INS2 may be composed of a single layer or multiple layers, and may include at least one inorganic insulating material and/or organic insulating material. For example, the second insulating layer INS2 may include at least one insulating material such as silicon nitride (SiNx), silicon oxide (SiOx), silicon oxynitride (SiOxNy), aluminum oxide (AlxOy), and a photoresist material, or may include other insulating materials.

Different contact electrodes CNE may be disposed and/or formed on the first and second ends EP1 and EP2 of the light emitting elements LD not covered by the second insulating layer INS2. For example, the first contact electrode CNE1 may be disposed on the first end EP1 of the first light emitting element LD1, and a portion of the second contact electrode CNE2 (also referred to as a first pixel electrode) may be disposed on the second end EP2 of the first light emitting element LD1. Another portion of the second contact electrode CNE2 may be disposed on the first end EP1 of the second light emitting element LD2, and the third contact electrode CNE3 (also referred to as a second pixel electrode) may be disposed on the second end EP2 of the second light emitting element LD2.

In FIG. 7, although the second contact electrode CNE2 disposed on the second end EP2 of the first light emitting element LD1 and the second contact electrode CNE2 disposed on the first end EP1 of the second light emitting element LD2 are shown as being separated from each other, the second contact electrode CNE2 disposed on the second end EP2 of the first light emitting element LD1 and the second contact electrode CNE2 disposed on the first end EP1 of the second light emitting element LD2 may be integrally or non-integrally connected with each other to constitute one second contact electrode CNE2. For example, when viewed on a plane, the second contact electrode CNE2 disposed on the second end EP2 of the first light emitting element LD1 and the second contact electrode CNE2 disposed on the first end EP1 of the second light emitting element LD2 may be integrally connected with each other. The second contact electrode CNE2 may be electrically connected to the first contact electrode CNE1 through the first light emitting element LD1, and may be electrically connected to the third contact electrode CNE3 through the second light emitting element LD2.

In FIG. 7, although the first alignment electrode ALE1 and the first contact electrode CNE1 are shown as being separated from each other, the first alignment electrode ALE1 and the first contact electrode CNE1 may be electrically connected to each other through at least one contact hole (or contact portion). Similarly, in FIG. 7, although the second alignment electrodes ALE2 and the third contact electrode CNE3 are shown as being separated from each other, the second alignment electrodes ALE2 and the third contact electrode CNE3 may be electrically connected to each other through at least one contact hole (or contact portion).

The first alignment electrode ALE1 and/or the first contact electrode CNE1 of each sub-pixel SPX may be connected to the pixel circuit PXC of the corresponding sub-pixel SPX through at least one contact hole (for example, the first contact hole CH1), and the second alignment electrodes ALE2 and/or the third contact electrode CNE3 of each sub-pixel SPX may be connected to the second power source line PL2 through at least one other contact hole.

The first contact electrode CNE1 may be disposed on the first alignment electrode ALE1 to overlap a portion of the first alignment electrode ALE1. The second contact electrode CNE2 may be disposed on the first and second alignment electrodes ALE1 and ALE2. The third contact electrode CNE3 may be disposed on the second alignment electrode ALE2 to overlap a portion of the second alignment electrode ALE2.

The first contact electrode CNE1, the second contact electrode CNE2, and/or the third contact electrode CNE3 may be formed on the same or different layers. For example, the relative positions and/or formation order of the first contact electrode CNE1, the second contact electrode CNE2, and the third contact electrode CNE3 may be variously changed according to embodiments.

In an embodiment, the first contact electrode CNE1 and the third contact electrode CNE3 may be formed on the second insulating layer INS2. The first contact electrode CNE1 and the third contact electrode CNE3 may be formed simultaneously or sequentially. Thereafter, the third insulating layer INS3 may be formed to cover the first contact electrode CNE1 and the third contact electrode CNE3, and the second contact electrode CNE2 may be formed in each emission area EA in which the third insulating layer INS3 is formed.

In another embodiment, the second contact electrode CNE2 may be formed on the second insulating layer INS2. Thereafter, the third insulating layer INS3 may be formed in each emission area EA to cover at least the second contact electrode CNE2, and the first contact electrode CNE1 and the third contact electrode CNE3 may be formed in each emission area EA in which the third insulating layer INS3 is formed. The first contact electrode CNE1 and the third contact electrode CNE3 may be formed simultaneously or sequentially.

In case that the contact electrodes CNE (for example, the first and second contact electrodes CNE1 and CNE2, or the second and third contact electrodes CNE2 and CNE3) disposed on the first end EP1 and the second end EP2 of each light emitting element LD are disposed on different layers, the contact electrodes CNE may be stably separated, and short circuit defects may be prevented.

In another embodiment, the first contact electrode CNE1, the second contact electrode CNE2, and the third contact electrode CNE3 may be disposed on the same layer of the display layer DPL and may be formed simultaneously or sequentially. The third insulating layer INS3 may be omitted. When the contact electrodes CNE are simultaneously formed on the same layer, a process of forming the pixels can be simplified and manufacturing efficiency can be improved.

According to an embodiment, the first contact electrode CNE1 may be directly formed on the first end EP1 of the first light emitting element LD1 and may be electrically connected to the first end EP1 of the first light emitting element LD1. The second contact electrode CNE2 may be directly formed on the second end EP2 of the first light emitting element LD1 and the first end EP1 of the second light emitting element LD2 and may be electrically connected to the second end EP2 of the first light emitting element LD1 and the first end EP1 of the second light emitting element LD2. The third contact electrode CNE3 may be directly formed on the second end EP2 of the second light emitting element LD2 and may be electrically connected to the second end EP2 of the second light emitting element LD2.

As in the embodiment of FIG. 4, in case each sub-pixel SPX includes the light emitting unit EMU having a parallel structure, the sub-pixel SPX may include only a pair of contact electrodes CNE respectively disposed on the first ends EP1 and the second ends EP2 of the light emitting elements LD.

The contact electrodes CNE may include at least one conductive material. In an embodiment, the contact electrodes CNE may include a transparent conductive material so that light emitted from the light emitting elements LD may be transmitted. For example, the contact electrodes CNE may include at least one conductive material of Indium Tin Oxide (ITO), Indium Zinc Oxide (IZO), Indium Tin Zinc Oxide (ITZO), Zinc Oxide (ZnO), and Indium Oxide (In₂O₃), or may include other transparent conductive materials.

In an embodiment, the display device DD may further include the light conversion layer CCL and the second bank BNK2 provided on the light emitting elements LD. The light conversion layer CCL may be disposed in each emission area EA in which the light emitting elements LD are disposed, and the second bank BNK2 may be disposed in the non-emission area NEA to overlap the first bank BNK1.

The second bank BNK2 may define (or partition) each emission area EA in which the light conversion layer CCL is to be formed. In an embodiment, the second bank BNK2 may be integrated with the first bank BNK1.

The second bank BNK2 may include a light blocking and/or reflective material such as a black matrix material. The second bank BNK2 may include the same or different material as the first bank BNK1.

The light conversion layer CCL may include wavelength conversion particles (or color conversion particles) that convert the wavelength and/or color of the light emitted from the light emitting elements LD and/or light scattering particles SCT that scatter the light emitted from the light emitting elements LD to increase light output efficiency. For example, the light conversion layer CCL including wavelength conversion particles including at least one type of quantum dots QD (for example, red, green, and/or blue quantum dots) and/or light scattering particles SCT may be provided on each light emitting unit EMU.

For example, in case that any one sub-pixel SPX is a red (or green) sub-pixel and blue light emitting elements LD are provided in the light emitting unit EMU of the sub-pixel SPX, the light conversion layer CCL including red (or green) quantum dots QD for converting blue light into red (or green) light may be disposed on the light emitting unit EMU of the sub-pixel SPX. The light conversion layer CCL may further include the light scattering particles SCT.

The fourth insulating layer INS4 may be formed on one surface of the substrate SUB including the light emitting units EMU of the sub-pixels SPX and/or light conversion layers CCL.

The fourth insulating layer INS4 may include an organic and/or inorganic insulating layer, and may substantially planarize the surface of the display layer DPL. The fourth insulating layer INS4 may protect the light emitting units EMU and/or the light conversion layers CCL.

The color filter layer CFL may be disposed on the fourth insulating layer INS4.

The color filter layer CFL may include color filters CF corresponding to the colors of the sub-pixels SPX. For example, the color filter layer CFL may include a first color filter CF1 disposed on the first light emitting unit EMU1 of the first sub-pixel SPX1, a second color filter CF2 disposed on the second light emitting unit EMU2 of the second sub-pixel SPX2, and a third color filter CF3 disposed on the third light emitting unit EMU3 of the third sub-pixel SPX3. In an embodiment, the first, second, and third color filters CF1, CF2, and CF3 may be disposed to overlap each other in the non-emission area NEA to block light transmission in the non-emission area NEA. In another embodiment, the first, second, and third color filters CF1, CF2, and CF3 may be formed on top of the first, second, and third light emitting units EMU1, EMU2, and EMU3 (in particular, the emission area EA of each of the first, second, and third light emitting units EMU1, EMU2, and EMU3) to be separated from each other, respectively. A separate light blocking pattern and the like may be disposed between the first, second, and third color filters CF1, CF2, and CF3.

The encapsulation layer ENC may be disposed on the color filter layer CFL. The encapsulation layer ENC may include at least one organic and/or inorganic insulating layer including a fifth insulating layer INS5. The fifth insulating layer INS5 may be formed over the entire display area DA to cover the pixel circuit layer PCL, the display layer DPL, and/or the color filter layer CFL.

The fifth insulating layer INS5 may be composed of a single layer or multiple layers, and may include at least one inorganic insulating material and/or organic insulating material. For example, the fifth insulating layer INS5 may include various types of organic/inorganic insulating materials such as silicon nitride (SiNx), silicon oxide (SiOx), silicon oxynitride (SiOxNy), or aluminum oxide (AlxOy).

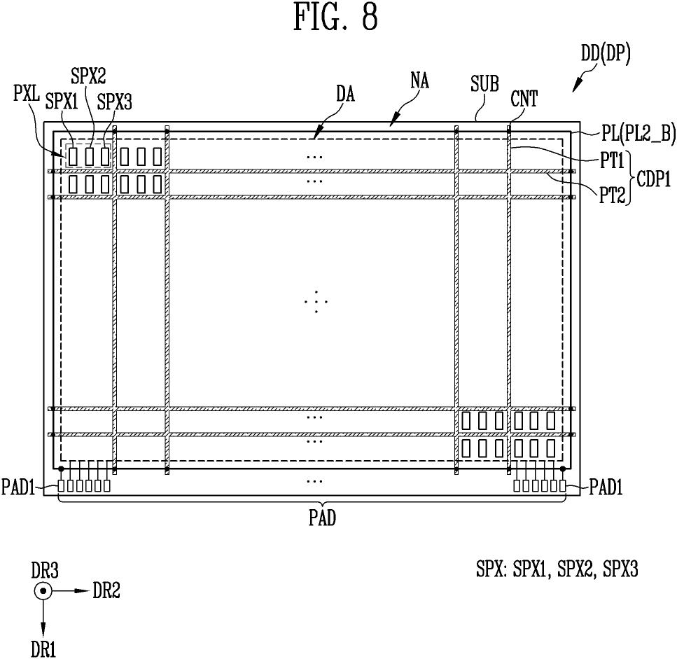

FIGS. 8 to 11 are plan views illustrating display devices DD according to embodiments of the disclosure. For example, FIGS. 8 to 11 show other modified embodiments of the display device DD of FIG. 3. In describing embodiments of FIGS. 8 to 11, components similar to or identical to those of the above-described embodiments, or components similar to or identical to each other are denoted by the same reference numerals, and detailed descriptions thereof will be omitted.

Referring to FIGS. 3 to 11, the display device DD may further include a first conductive pattern CDP1 provided at least in the display area DA to be disposed between the sub-pixels SPX and/or the pixels PXL. In an embodiment, the first conductive pattern CDP1 may be electrically connected to at least one power source line PL disposed in the non-display area NA. For example, the first conductive pattern CDP1 may be electrically connected to the second bus line PL2_B disposed in the non-display area NA. The first conductive pattern CDP1 may have various shapes, sizes, and/or structures, and may be directly or indirectly connected to the second bus line PL2_B. Accordingly, when static electricity is generated in the display device DD, charges may be rapidly discharged through the first conductive pattern CDP1. Accordingly, damage to the pixels PXL due to electrostatic discharge can be prevented or reduced.

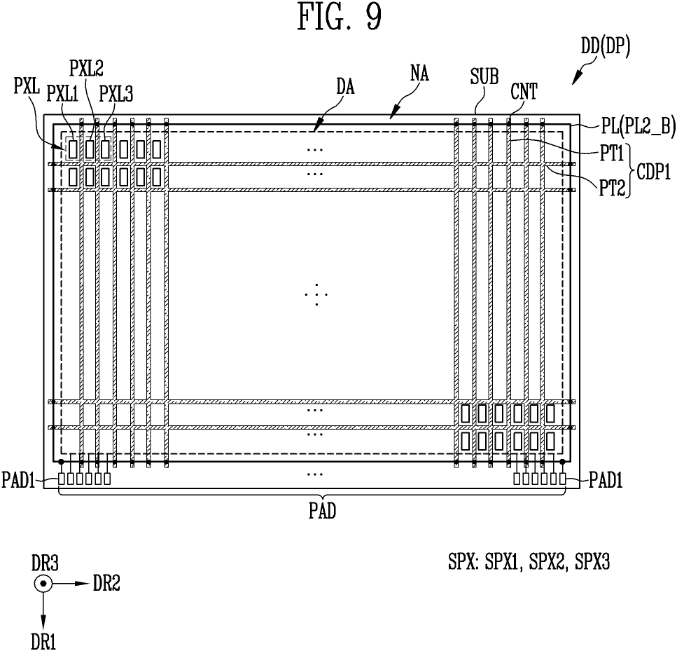

Referring to FIGS. 8 and 9, the first conductive pattern CDP1 may be a mesh-shaped pattern including first pattern portions PT1 extending in the first direction DR1 in the display area DA and second pattern portions PT2 extending in the second direction DR2 in the display area DA. The first pattern portions PT1 and the second pattern portions PT2 may be integrally connected and/or formed with each other, but embodiments of the disclosure are not limited thereto.

In an embodiment, as shown in FIG. 8, the first pattern portions PT1 may be disposed between the pixels PXL at an interval corresponding to an interval between the pixels PXL. In another embodiment, as shown in FIG. 9, the first pattern portions PT1 may be disposed between the sub-pixels SPX (for example, between the light emitting units EMU of the sub-pixels SPX) at an interval between the sub-pixels SPX (for example, an interval between the light emitting units EMU of the sub-pixels SPX). The interval, position, and/or shape of the first pattern portions PT1 may be variously changed according to embodiments.

In an embodiment, the first conductive pattern CDP1 may extend to the non-display area NA to overlap the second bus line PL2_B, and may be directly connected to the second bus line PL2_B through at least one contact portion CNT (for example, through multiple contact portions CNT each including at least one contact hole and/or via hole). For example, the first pattern portions PT1 and the second pattern portions PT2 may extend to the non-display area NA, and the first pattern portions PT1 and the second pattern portions PT2 may be directly connected to the second bus line PL2_B through the contact portions CNT at both ends, respectively.

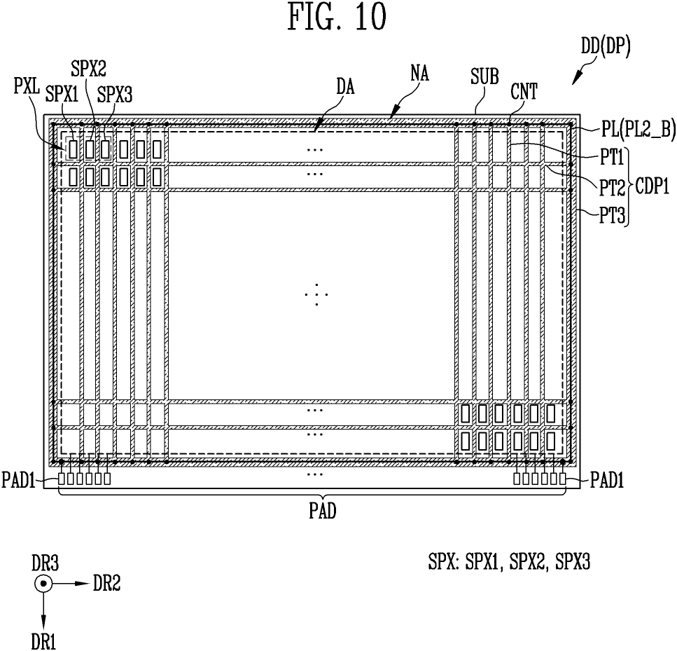

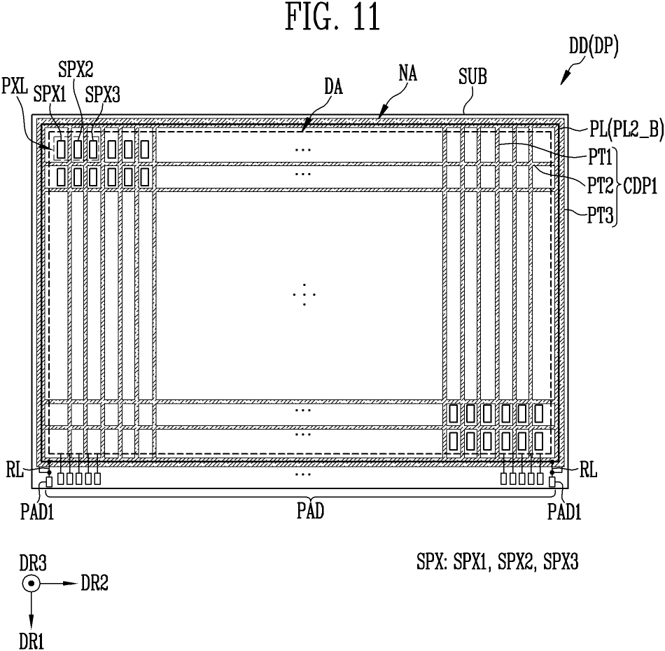

Referring to FIGS. 10 and 11, the first conductive pattern CDP1 may further include a third pattern portion PT3 disposed in the non-display area NA and connected to the first pattern portions PT1 and the second pattern portions PT2. The third pattern portion PT3 may be integrally connected and/or formed with the first pattern portions PT1 and/or the second pattern portions PT2, but embodiments of the disclosure are not limited thereto.

In an embodiment, the third pattern portion PT3 may surround (for example, completely surround) the display area DA when viewed on a plane. Accordingly, the pixels PXL may be effectively protected.

The first conductive pattern CDP1 may be directly connected to the second bus line PL2_B, or may be electrically connected to the second bus line PL2_B through at least one routing line RL and/or at least one first pad PAD1. In an embodiment, as shown in FIG. 10, the third pattern portion PT3 of the first conductive pattern CDP1 may overlap the second bus line PL2_B and may be directly connected to the second bus line PL2_B through multiple contact portions CNT. In another embodiment, as shown in FIG. 10, the third pattern portion PT3 of the first conductive pattern CDP1 may not be directly connected to the second bus line PL2_B, and may be connected to at least one first pad PAD1 and/or at least one routing line RL connected to the first pad PAD1.

In an embodiment, the first conductive pattern CDP1 may be disposed on the same layer as at least some of the pixel electrodes provided in the light emitting units EMU of the pixels PXL. For example, the first conductive pattern CDP1 may be disposed in the display layer DPL together with the light emitting elements LD and the pixel electrodes (for example, the alignment electrodes ALE and the contact electrodes CNE) constituting each of the light emitting units EMU, and may be disposed on the same layer as the first and third contact electrodes CNE1 and CNE3 of the pixels PXL.

In an embodiment, the first conductive pattern CDP1 may be formed simultaneously with the first and third contact electrodes CNE1 and CNE3 of the pixels PXL, and thus the first conductive pattern CDP1 may be formed without adding a separate process step. Since the first conductive pattern CDP1 is disposed in the display layer DPL above the circuit layer PCL, the pixels PXL may be effectively protected from static electricity that may be generated on the top surface of the display device DD.

In an embodiment, the first conductive pattern CDP1 may be formed of an independent pattern separated from the pixel electrodes provided in each of the light emitting units EMU. For example, the first conductive pattern CDP1 may be formed of an independent pattern disposed on the same layer as at least some of the contact electrodes CNE provided in the light emitting units EMU (for example, the first and third contact electrodes CNE1 and CNE3) and separated from the contact electrodes CNE of the light emitting units EMU.

In another embodiment, the first conductive pattern CDP1 may be disposed on the same layer as at least some of the contact electrodes CNE provided in the light emitting units EMU (for example, first contact electrodes CNE1 and/or third contact electrodes CNE3), and may be integrally connected to and/or formed with contact electrodes electrically connected to the second power source line PL2 (for example, the third contact electrodes CNE3 of the light emitting units EMU).

FIGS. 12 to 14 are plan views illustrating display layers DPL of the display area DA according to embodiments of the disclosure. FIGS. 12 to 14 show different embodiments of the structure of the display layer DPL centered on the first pixel area PXA1 and the second pixel area PXA2 in which the first pixel PXL1 and the second pixel PXL2 of FIG. 6 are disposed. For example, FIGS. 12 to 14 show different embodiments depending on whether and how the pixel electrodes electrically connected to the second power source line PL2 (for example, the third contact electrodes CNE3 of the pixels PXL) are connected to the first conductive pattern CDP1.

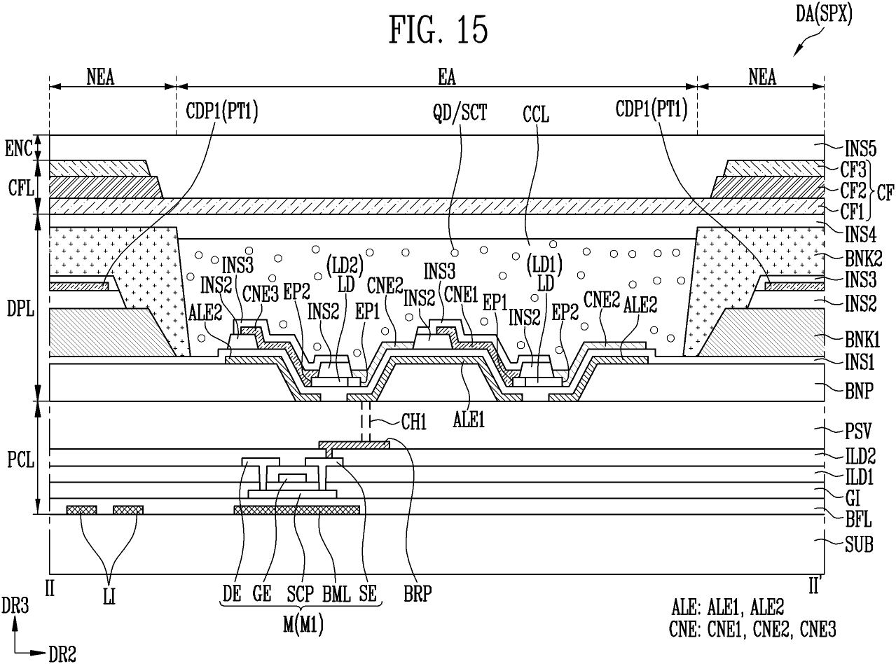

FIG. 15 is a schematic cross-sectional view illustrating a display area DA according to an embodiment of the disclosure. For example, FIG. 15 shows a modified embodiment of FIG. 7, and schematically shows a cross section of the display area DA corresponding to line II - II' of FIG. 12.

In describing embodiments of FIGS. 12 to 15, components similar to or identical to those of the above-described embodiments, or components similar to or identical to each other are denoted by the same reference numerals, and detailed descriptions thereof will be omitted.

Referring to FIGS. 12 to 15, each light emitting unit EMU may include at least a pair of alignment electrodes ALE (for example, the first and second alignment electrodes ALE1 and ALE2), at least one light emitting element LD (for example, the first and second light emitting elements LD1 and LD2), and at least a pair of contact electrodes CNE (for example, the first, second, and third contact electrodes CNE1, CNE2, and CNE3).

In an embodiment, the light emitting unit EMU may include a first alignment electrode ALE1 positioned in a central portion of the emission area EA, and multiple second alignment electrodes ALE2 positioned on both sides of the first alignment electrode ALE1. In an embodiment, the second alignment electrode ALE2 positioned on the left side of the first alignment electrode ALE1 may be integrally connected to the second alignment electrode ALE2 of a neighboring sub-pixel SPX adjacent to the left side of a corresponding sub-pixel SPX (for example, the second alignment electrode ALE2 positioned on the right side of the first alignment electrode ALE1 in the neighboring sub-pixel SPX). Similarly, the second alignment electrode ALE2 positioned on the right side of the first alignment electrode ALE1 may be integrally connected to the second alignment electrode ALE2 of the neighboring sub-pixel SPX adjacent to the right side of the corresponding sub-pixel SPX (for example, the second alignment electrode ALE2 positioned on the left side of the first alignment electrode ALE1 in the neighboring sub-pixel SPX). Also, the second alignment electrodes ALE2 disposed in the display area DA may be integrally or non-integrally connected with each other within and/or around the display area DA.

The first alignment electrode ALE1 of each of the sub-pixels SPX may be connected to the pixel circuit PXC of the corresponding sub-pixel SPX through each first contact hole CH1, and may be connected to the first contact electrode CNE1 of the corresponding sub-pixel SPX through each third contact hole CH3. Accordingly, the pixel circuit PXC of each sub-pixel SPX may be electrically connected to the first contact electrode CNE1 of the light emitting unit EMU.

Meanwhile, the first alignment electrodes ALE1 provided in the display area DA may be formed to be connected to each other first in a process of manufacturing the pixels. For example, the first alignment electrodes ALE1 may be formed to be integrally connected to floating patterns FPT to configure the first alignment line. The floating patterns FPT may be electrically connected to the first power source line PL1 (for example, the (1-2)th sub-power source lines PL1_H) of the circuit layer PCL through fifth contact holes CH5. Accordingly, in a process of aligning the light emitting elements LD, a first alignment signal may be supplied to the first alignment line through the first power source line PL1. After the process of aligning the light emitting elements LD is completed, the connection between the first alignment electrodes ALE1 and the first power source line PL1 may be disconnected by cutting the first alignment line around the fifth contact holes CH5. For example, the first alignment line may be separated into the first alignment electrodes ALE1 and the floating patterns FPT by cutting the first alignment line in disconnection areas OPA (also referred to as open areas or etching areas) located around the floating patterns FPT (for example, upper and lower areas of the floating patterns FPT). The first alignment electrodes ALE1 of adjacent sub-pixels SPX may be separated by cutting the first alignment line between adjacent pixel rows. Accordingly, since the first alignment electrodes ALE1 of the sub-pixels SPX are separated from each other, the sub-pixels SPX may be driven individually.

The second alignment electrodes ALE2 of the sub-pixels SPX may be spaced apart from the first alignment electrodes ALE1 and positioned around the first alignment electrodes ALE1. The second alignment electrodes ALE2 of the sub-pixels SPX may be integrally or non-integrally connected with each other, and may be commonly connected to the second power source line PL2. For example, the second alignment electrodes ALE2 of the sub-pixels SPX adjacent in the first direction DR1 and/or the second direction DR2 may be integrally connected with each other.

The second alignment electrodes ALE2 may be connected to the second power source line PL2 (for example, the (2-2)th sub-power source lines PL2_H) through second contact holes CH2. The second alignment electrodes ALE2 may receive a second alignment signal through the second power source line PL2 in the process of aligning the light emitting elements LD. The first alignment signal and the second alignment signal may have different waveforms, potentials and/or phases. Accordingly, since an electric field is formed between the first alignment line and the second alignment electrodes ALE2 (or the second alignment line formed by the second alignment electrodes ALE2), the light emitting elements LD may be aligned between the first alignment line and the second alignment electrodes ALE2.

During the operation of the display device DD, the second pixel power source VSS may be supplied to the second alignment electrodes ALE2 through the second power source line PL2. Accordingly, a driving current may flow through each sub-pixel SPX.

The first alignment electrodes ALE1 and the second alignment electrodes ALE2 may extend along the first direction DR1 in the emission areas EA of the light emitting units EMU, and may be spaced apart from each other along the second direction DR2. The shape, size, number, position, and/or relative position of the first alignment electrodes ALE1 and the second alignment electrodes ALE2 may be variously changed according to embodiments.

The first bank BNK1 may be disposed in the display area DA in which the first alignment electrodes ALE1 and the second alignment electrodes ALE2 are disposed. The first bank BNK1 may include openings in the emission areas EA of the sub-pixels SPX, and may surround the emission areas EA when viewed on a plane. The first bank BNK1 may also be opened in areas where the first alignment line is cut in order to separate the first alignment line into the first alignment electrodes ALE1 (for example, the disconnection areas OPA around the floating patterns FPT and an area between adjacent pixel rows) and in a peripheral area thereof.

The light emitting elements LD may be disposed and/or aligned between the first and second alignment electrodes ALE1 and ALE2 in each emission area EA. The expression “the light emitting elements LD are disposed and/or aligned between the first and second alignment electrodes ALE1 and ALE2” may mean that at least a portion of each of the light emitting elements LD is positioned in an area between the first and second alignment electrodes ALE1 and ALE2 when viewed on a plane. Each light emitting element LD may or may not overlap the first alignment electrode ALE1 and/or the second alignment electrode ALE2.

In an embodiment, the light emitting elements LD may be prepared in a dispersed form in a solution, and may be supplied to each emission area EA through an inkjet method, a slit coating method, or the like. When the first and second alignment signals are respectively applied to the first and second alignment electrodes ALE1 and ALE2 (or the first and second alignment lines) of the sub-pixels SPX, the light emitting elements LD may be aligned between the first and second alignment electrodes ALE1 and ALE2. After the light emitting elements LD are aligned, a solvent may be removed by a drying process or the like.

In an embodiment, the light emitting elements LD may include first light emitting elements LD1 aligned between the first alignment electrode ALE1 and any one second alignment electrode ALE2 (for example, the second alignment electrode ALE2 positioned on the right side of the first alignment electrode ALE1), and second light emitting elements LD2 aligned between the first alignment electrode ALE1 and the other second alignment electrode ALE2 (for example, the second alignment electrode ALE2 positioned on the left side of the first alignment electrode ALE1). The first contact electrode CNE1 may be disposed on the first ends EP1 of the first light emitting elements LD1, and a portion of the second contact electrode CNE2 may be disposed on the second ends EP2 of the first light emitting elements LD1. Another portion of the second contact electrode CNE2 may be disposed on the first ends EP1 of the second light emitting elements LD2, and the third contact electrode CNE3 may be disposed on the second ends EP2 of the second light emitting elements LD2.

Each first contact electrode CNE1 may be disposed on the first ends EP1 to be electrically connected to the first ends EP1 of the first light emitting elements LD1 aligned in a corresponding emission area EA, and may be electrically connected to each first alignment electrode ALE1 through each third contact hole CH3. Also, each first contact electrode CNE1 may be electrically connected to the pixel circuit PXC of the corresponding sub-pixel SPX through each first alignment electrode ALE1, and may be electrically connected to the first power source line PL1 (for example, the (1-2)th sub-power source line PL1_H) through the pixel circuit PXC. In an embodiment, each first contact electrode CNE1 may be an anode electrode provided in the light emitting unit EMU of the corresponding sub-pixel SPX.

In an embodiment, the third contact holes CH3 of the sub-pixels SPX may be disposed outside of the emission area EA and may be formed in an area that does not overlap the first bank BNK1. Accordingly, the third contact holes CH3 may be formed on a relatively flat area by avoiding an area in which a step is generated by the first bank BNK1.

Each second contact electrode CNE2 may be disposed on the second ends EP2 of the first light emitting elements LD1 and the first ends EP1 of the second light emitting elements LD2 to be electrically connected to the second ends EP2 of the first light emitting elements LD1 and the first ends EP1 of the second light emitting elements LD2 aligned in the corresponding emission area EA. Each second contact electrode CNE2 may be electrically connected to the first and third contact electrodes CNE1 and CNE3 through the first and second light emitting elements LD1 and LD2.

Each third contact electrode CNE3 may be disposed on the second ends EP2 of the second light emitting elements LD2 to be electrically connected to the second ends EP2 of the second light emitting elements LD2 aligned in the corresponding emission area EA, and may be electrically connected to each second alignment electrode ALE2 through each fourth contact hole CH4. Each third contact electrode CNE3 may be electrically connected to the second power source line PL2 (for example, the (2-2)th sub-power source line PL2_H) through each second alignment electrode ALE2. In an embodiment, each third contact electrode CNE3 may be a cathode electrode provided in the light emitting unit EMU of the corresponding sub-pixel SPX.

In an embodiment, the fourth contact holes CH4 of the sub-pixels SPX may be disposed outside of the emission area EA and may be formed in an area that does not overlap the first bank BNK1. The fourth contact holes CH4 may be formed on a relatively flat area by avoiding an area in which a step is generated by the first bank BNK1.

The first conductive pattern CDP1 may be disposed around the light emitting units EMU. The first conductive pattern CDP1 may be disposed between the light emitting units EMU of the pixels PXL. For example, the first conductive pattern CDP1 may surround the light emitting unit EMU of each of the sub-pixels SPX or the light emitting units EMU of each of the pixels PXL (for example, the first, second, and third light emitting units EMU1, EMU2, and EMU3 of each pixel PXL) when viewed on a plane.

The first conductive pattern CDP1 may be disposed on the same layer as at least one of the contact electrodes CNE provided in each light emitting unit EMU. For example, the first conductive pattern CDP1 may be disposed on the same layer as the first and third contact electrodes CNE1 and CNE3 of the light emitting units EMU.

In an embodiment, the first conductive pattern CDP1 may not be directly connected to the light emitting units EMU of the pixels PXL. For example, as shown in FIG. 12, the first conductive pattern CDP1 and the contact electrodes CNE may be separated from each other and may be formed as independent patterns.

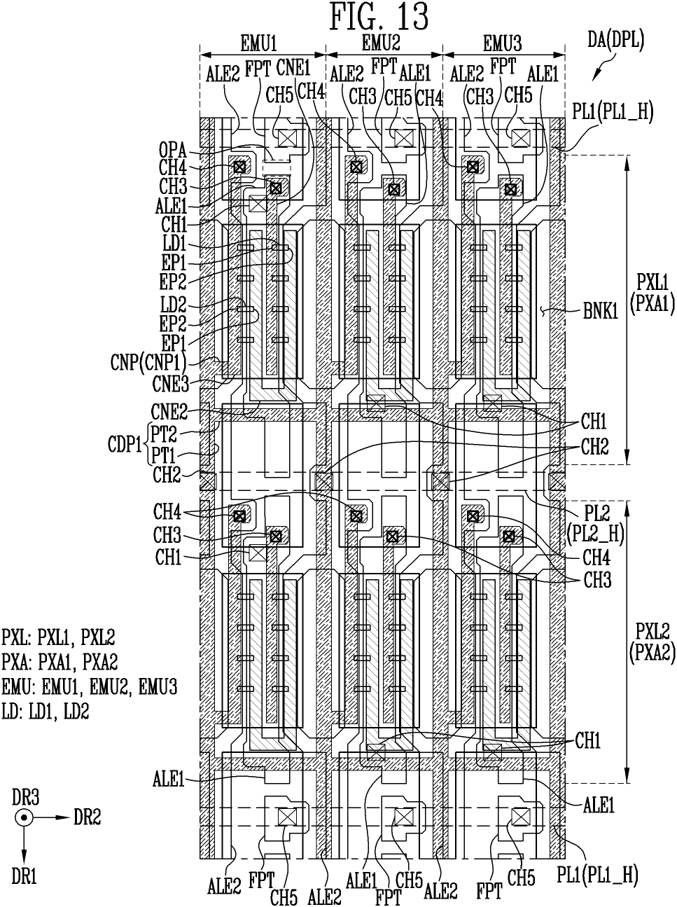

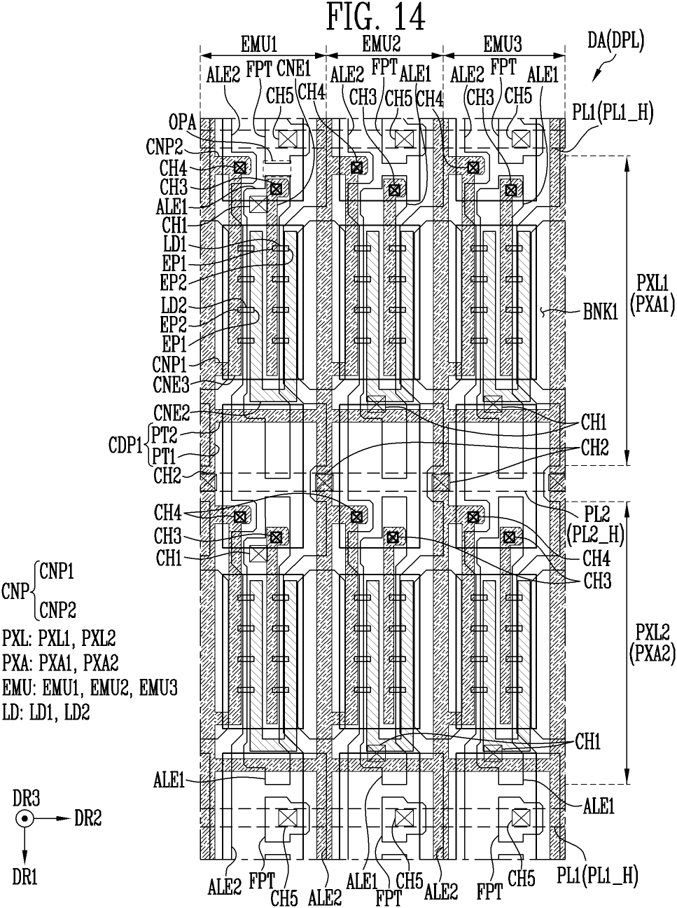

In another embodiment, the first conductive pattern CDP1 may be directly connected to the third contact electrodes CNE3 of the pixels PXL as shown in FIGS. 13 and 14. For example, as in the embodiment of FIG. 13, first connection portions CNP1 may be provided between the first conductive pattern CDP1 and the third contact electrodes CNE3, and the first conductive pattern CDP1, the third contact electrodes CNE3, and the first connection portions CNP1 may be integrally connected and/or formed with each other. The first connection portions CNP1 may also be viewed as a portion of the first conductive pattern CDP1 and/or the third contact electrodes CNE3.

In an embodiment, at least one third contact electrode CNE3 may be connected to the first conductive pattern CDP1 through at least two connection portions CNP. For example, a first connection portion CNP1 and a second connection portion CNP2 may be provided at different ends of each of the third contact electrodes CNE3, respectively, and the first conductive pattern CDP1, the third contact electrodes CNE3, the first connection portions CNP1, and second connection portions CNP2 may be integrally connected and/or formed with each other. The first connection portions CNP1 and the second connection portions CNP2 may also be viewed as a portion of the first conductive pattern CDP1 and/or the third contact electrodes CNE3.

In case that the third contact electrodes CNE3 are connected to the first conductive pattern CDP1 through at least two connection portions CNP, respectively, the third contact electrodes CNE3 may be more stably connected to the first conductive pattern CDP1 and the second power source line PL2. Accordingly, dark spot defects of the pixels PXL may be prevented or reduced.

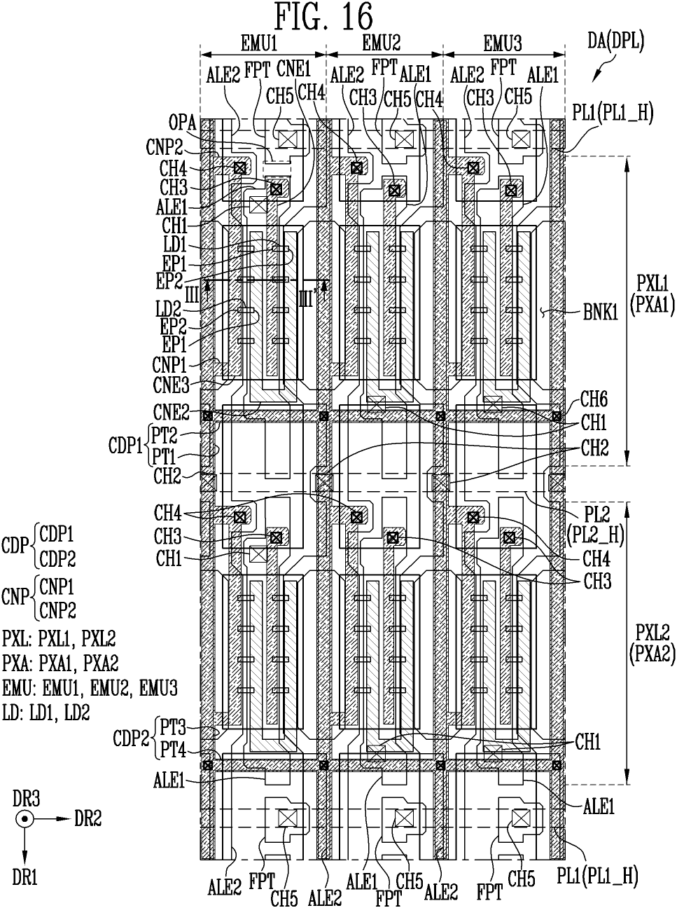

FIG. 16 is a plan view illustrating a display layer DPL of the display area DA according to an embodiment of the disclosure. For example, FIG. 16 shows an embodiment of a structure of the display layer DPL centered on the first pixel area PXA1 and the second pixel area PXA2 in which the first pixel PXL1 and the second pixel PXL2 of FIG. 6 are disposed. In FIG. 16, a modified embodiment of the embodiment of FIG. 14 is described, but embodiments of the disclosure are not limited thereto. For example, the structure of the embodiment of FIG. 16 may also be applied to the embodiment of FIGS. 12 or 13.

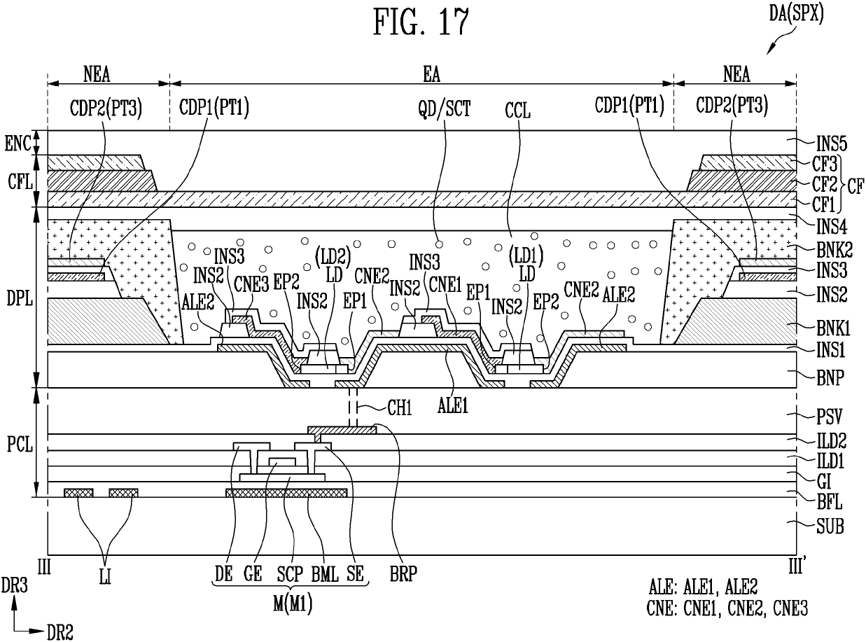

FIG. 17 is a schematic cross-sectional view illustrating the display area DA according to an embodiment of the disclosure. For example, FIG. 17 is a modified embodiment of the embodiment of FIG. 15 and schematically shows a cross section of the display area DA corresponding to line III-III' of FIG. 16.

In describing embodiments of FIGS. 16 and 17, components similar to or identical to those of the above-described embodiments are denoted by the same reference numerals, and detailed description thereof will be omitted.

Referring to FIGS. 16 and 17, the display device DD may include a multi-layered conductive pattern CDP including a first conductive pattern CDP1 and a second conductive pattern CDP2 disposed on different layers. The second conductive pattern CDP2 may overlap the first conductive pattern CDP1 and may be electrically connected to the first conductive pattern CDP1 through sixth contact holes CH6. Accordingly, the resistance of the conductive pattern CDP can be reduced.

In an embodiment, the second conductive pattern CDP2 may be disposed on the same layer as at least one of the contact electrodes CNE provided in each of the light emitting units EMU of the pixels PXL. For example, the second conductive pattern CDP2 may be simultaneously formed on the same layer as the second contact electrodes CNE2 in a process of forming the second contact electrodes CNE2 of the light emitting units EMU. In FIG. 17, each of the second contact electrodes CNE2 is shown as being disposed lower than the third insulating layer INS3, but embodiments of the disclosure are not limited thereto. For example, the second contact electrodes CNE2 may be formed after the first and third contact electrodes CNE1 and CNE3 and the third insulating layer INS3 are formed, and a portion of the second contact electrodes CNE2 may be disposed on the third insulating layer INS3.

The second conductive pattern CDP2 may be formed together with the second contact electrodes CNE2, and may be formed to be spaced apart from the second contact electrodes CNE2. For example, the second conductive pattern CDP2 and the second contact electrodes CNE2 may be formed as independent patterns separated from each other.

In an embodiment, the first conductive pattern CDP1 and the second conductive pattern CDP2 may have shapes and/or sizes corresponding to each other, and may be formed of mesh-shaped patterns. For example, the first conductive pattern CDP1 may be a mesh-shaped pattern including first pattern portions PT1 and second pattern portions PT2 extending in the first direction DR1 and the second direction DR2 in the display area DA, respectively. Similarly, the second conductive pattern CDP2 may be a mesh-shaped pattern including third pattern portions PT3 and fourth pattern portions PT4 extending in the first direction DR1 and the second direction DR2 in the display area DA, respectively. The third pattern portions PT3 may overlap the first pattern portions PT1, and the fourth pattern portions PT4 may overlap the second pattern portions PT2.

According to various embodiments of the disclosure as described above, the display device DD may include a single-layer or multi-layer conductive pattern CDP (for example, the first conductive pattern CDP1 and/or the second conductive pattern CDP2) provided in the display layer DPL together with the light emitting units EMU of the pixels PXL. The first conductive pattern CDP1 and/or the second conductive pattern CDP2 may be disposed between the pixels PXL and/or the sub-pixels SPX (for example, between the light emitting units EMU of the pixels PXL and/or the sub-pixels SPX), and may be formed of a mesh-shaped pattern.

According to some embodiments, when static electricity is generated, a discharge path of the static electricity may be formed through the first conductive pattern CDP1 and/or the second conductive pattern CDP2, so that the charge may be rapidly discharged. Accordingly, the pixels PXL can be effectively protected, and damage and/or driving failure of the pixels PXL due to electrostatic discharge can be prevented.

According to some embodiments, since the color filter layer CFL and the encapsulation layer ENC are directly formed on one surface of the substrate SUB on which the light emitting units EMU of the pixels PXL are provided, even in the display device DD having a structure in which static electricity is easily introduced into the light emitting units EMU, charges may be rapidly discharged through the first conductive pattern CDP1 and/or the second conductive pattern CDP2. Accordingly, damage and/or driving failure of the pixels PXL due to electrostatic discharge can be effectively prevented. The first conductive pattern CDP1 and/or the second conductive pattern CDP2 may act as a shield electrode between the contact electrodes CNE. Accordingly, operating characteristics of the pixels PXL may be stabilized even in the display device DD having a high resolution.

In an embodiment, the first conductive pattern CDP1 and/or the second conductive pattern CDP2 may be electrically connected to the second power source line PL2 and may lower the resistance of the second power source line PL2. Accordingly, a voltage drop of the second pixel power source VSS can be prevented or reduced, and a deviation in luminance of the pixels PXL due to the voltage drop of the second pixel power source VSS can be prevented or reduced.

The display device according to the embodiments of the disclosure may include the conductive pattern provided in the display layer together with the light emitting units of the pixels. According to the embodiments of the disclosure, when static electricity is generated, charges may be rapidly discharged through the conductive pattern. Accordingly, damage and/or driving failure of the pixels due to electrostatic discharge can be prevented or reduced.

In an embodiment, the conductive pattern may be electrically connected to the second power source line. Accordingly, a voltage drop of the second pixel power source can be prevented or reduced, and a deviation in luminance of the pixels due to the voltage drop of the second pixel power source can be prevented or reduced.

The effects according to the embodiments are not limited by the contents described above, and more various effects are included in the disclosure.

Although the technical idea of the disclosure has been described in detail through the above-described embodiments, it should be noted that the above-described embodiments are for illustrative purpose only and are not intended to limit the disclosure. In addition, those skilled in the art may understand that various modifications are possible within the scope of the technical spirit of the disclosure.

The scope of the disclosure is not limited by the detailed descriptions of the disclosure, and should be defined by the accompanying claims. Furthermore, all changes or modifications of the disclosure derived from the meanings and scope of the claims, and equivalents thereof should be construed as being included in the scope of the disclosure.

What is claimed is:

1. A display device comprising:
a substrate including a display area and a non-display area;
pixels disposed in the display area and including light emitting units;
a first conductive pattern disposed between the pixels; and
a power source line disposed in the non-display area and electrically connected to the first conductive pattern, wherein
each of the light emitting units includes:
a light emitting element;
a first pixel electrode disposed on a first end of the light emitting element; and
a second pixel electrode disposed on a second end of the light emitting element, and
wherein the first conductive pattern and the second pixel electrode are disposed on a same layer.

2. The display device of claim 1, wherein the first conductive pattern includes:
first pattern portions extending in a first direction in the display area; and
second pattern portions extending in a second direction in the display area.

3. The display device of claim 2, wherein the first conductive pattern further includes a third pattern portion disposed in the non-display area and connected to the first pattern portions and the second pattern portions.

4. The display device of claim 3, wherein the third pattern portion surrounds the display area when viewed on a plane.

5. The display device of claim 1, wherein
the first conductive pattern extends to the non-display area and overlaps the power source line, and
the first conductive pattern is directly connected to the power source line.

6. The display device of claim 1, further comprising:
a first pad electrically connected to the power source line, wherein
the first conductive pattern is not directly connected to the power source line, and
the first conductive pattern is electrically connected to the first pad.

7. The display device of claim 1, wherein the first conductive pattern and the second pixel electrodes of the light emitting units are separated from each other.

8. The display device of claim 1, wherein the power source line is electrically connected to the second pixel electrodes of the light emitting units.

9. The display device of claim 8, wherein the first conductive pattern and the second pixel electrodes of the light emitting units are integral with each other.

10. The display device of claim 1, wherein
the first pixel electrodes of the light emitting units and the first conductive pattern are disposed on different layers, and
the first pixel electrodes of the light emitting units and the second pixel electrodes of the light emitting units are disposed on different layers.

11. The display device of claim 10, further comprising:
a second conductive pattern overlapping the first conductive pattern and electrically connected to the first conductive pattern.

12. The display device of claim 11, wherein the second conductive pattern and the first pixel electrodes of the light emitting units are disposed on a same layer.

13. The display device of claim 11, wherein
the first conductive pattern has a mesh shape and includes:
first pattern portions extending in a first direction in the display area; and
second pattern portions extending in a second direction in the display area, and
the second conductive pattern has a mesh shape and includes:
third pattern portions overlapping the first pattern portions; and
fourth pattern portions overlapping the second pattern portions.

14. The display device of claim 11, wherein the second conductive pattern and the first pixel electrodes of the light emitting units are separated from each other.

15. The display device of claim 1, wherein the pixels further include pixel circuits electrically connected to the respective light emitting units.

16. The display device of claim 15, further comprising:
a circuit layer disposed on a surface of the substrate and including the power source line and the pixel circuits of the pixels; and
a display layer disposed on the circuit layer and including the first conductive pattern and the light emitting units of the pixels.

17. The display device of claim 16, further comprising:
a color filter layer and an encapsulation layer that are disposed above the display layer.

18. The display device of claim 17, wherein the color filter layer and the encapsulation layer are disposed above the surface of the substrate where the circuit layer and the display layer are disposed.

19. A display device comprising:
pixels including light emitting units, each of the light emitting units including:
a light emitting element; and
pixel electrodes electrically connected to the light emitting element; and
a conductive pattern having a mesh shape and disposed around the pixels to surround the light emitting units, wherein
the conductive pattern and at least one of the pixel electrodes are disposed on a same layer.

20. The display device of claim 19, further comprising:
a power source line electrically connected to the conductive pattern.
